(19) United States
(12) Patent Application Publication
(10) Pub. No.: US 2026/0047234 A1
(43) Pub. Date: Feb. 12, 2026

(54) NANOMATERIAL-BASED SEMICONDUCTOR STRUCTURES AND METHOD OF MANUFACTURING THE SAME

(71) Applicant: MELLANOX TECHNOLOGIES, LTD., Yokneam (IL)

(72) Inventors: Elad MENTOVICH, Tel Aviv (IL); Isabelle CESTIER, Haifa (IL); Ran HASSON RUSO, Pardes Hanna-Karkur (IL)

(73) Assignee: MELLANOX TECHNOLOGIES, LTD., Yokneam (IL)

(21) Appl. No.: 18/800,868

(22) Filed: Aug. 12, 2024

(51) Int. Cl. H01L 33/04; H01L 29/423; H01L 33/00; H01L 33/10

(52) U.S. Cl. CPC H10H 20/811; H10D 30/6735; H10H 20/01; H10H 20/814

(57) ABSTRACT

Some embodiments of the present disclosure are directed to a nanomaterial-based semiconductor device and method of manufacturing the same. Integration of nanostructures in a semiconductor layer may reduce the size of the semiconductor devices and may lower the applied voltage, thereby reducing heating of the structure. Further, the solution may simplify the manufacturing process by eliminating the need to dope the semiconductor layer and may reduce the size of the semiconductor devices. Moreover, embedding the nanostructures in the semiconductor layer may enable precise control of the doping of the semiconductor layer.

### TECHNOLOGICAL FIELD

The present disclosure relates to a nanomaterial-based semiconductor structure and a method of manufacturing the same.

### BACKGROUND

With demand for electronics with lower-power consumption and smaller device size increasing, electronics manufacturers are developing new devices to fulfill these demands. Some of the structures being developed to meet this demand are nanomaterial-based semiconductor structures.

### GENERAL DESCRIPTION

In one aspect, the present disclosure is directed to a semiconductor device that may include a doped region including a nanostructure as a dopant of the doped region, a first tunnel junction configured to electrically isolate the nanostructure from a source region, and a second tunnel junction configured to electrically isolate the nanostructure from a drain region. In some embodiments, the semiconductor device may include a substrate region and an insulating region disposed between the doped region and the substrate region, where the insulating region may be configured to insulate the doped region from the substrate region. Further, the doped region may include a doped silicon region. Additionally, or alternatively, the nanostructure may include a quantum dots layer.

In some embodiments, the doped region may include an intrinsic semiconductor material doped with the nanostructure. Further, the nanostructure may have a largest dimension of 5 nanometers or less. Additionally, or alternatively, the first tunnel junction may have a first thickness between the nanostructure and the source region of 3 nanometers or less, and the second tunnel junction may have a second thickness between the nanostructure and the drain region of 3 nanometers or less.

In some embodiments, the substrate region may include intrinsic silicon. Further, the insulating region may include silicon dioxide. Additionally, or alternatively, the insulating region may include a dielectric material.

In some embodiments, the source region and the drain region may be disposed on the doped region. Further, the semiconductor device may include a gate region configured for controlling a current through the doped region. Additionally, or alternatively, the semiconductor device may include a gate capacitor disposed between the gate region and the doped region.

In some embodiments, the gate capacitor may include an oxide region. Further, the doped region may be a first doped region, where the nanostructure may be a first nanostructure, the source region may be a first source region, the drain region may be a first drain region, and the insulating region may be a first insulating region. Additionally, or alternatively, the semiconductor device may include a second doped region including a second nanostructure as a dopant of the second doped region, a third tunnel junction configured to electrically isolate the second nanostructure from a second source region, and a fourth tunnel junction configured to electrically isolate the second nanostructure from a second drain region.

In some embodiments, a second insulating region may be disposed between the first doped region and the second doped region, where the second insulating region may be configured to insulate the first doped region from the second doped region. Further, the semiconductor device may include a gate region configured for controlling a current through the first doped region and the second doped region. Additionally, or alternatively, the semiconductor device may include a first gate region configured for controlling a first current through the first doped region, a second gate region configured for controlling a second current through the second doped region, where the second gate region may include a first distributed Bragg reflector, and a gate capacitor disposed between the second gate region and the second doped region.

In some embodiments, the second insulating region may include a second distributed Bragg reflector. Further, the second doped region may be configured to emit light. Additionally, or alternatively, a laser device may include the semiconductor device, where a semiconductor layer may be configured as an active region for light emission, a second gate electrode may be configured to be reflective and at least partially transparent, and a reflective surface.

In another aspect, the present disclosure is directed to an optical device that may include a semiconductor structure including a first doped region including a first nanostructure as a first dopant of the first doped region, a substrate region, and a first insulating region disposed between the first doped region and the substrate region, where the first insulating region may be configured to insulate the first doped region from the substrate region. In some embodiments, the optical device may include a diode including a second doped region including a second nanostructure as a second dopant of the second doped region, where the second doped region may be configured to emit light, a gate region configured for controlling a current through the second doped region, where the gate region may include a first distributed Bragg reflector, and a second insulating region disposed between the second doped region and the first doped region, where the second insulating region may be configured to insulate the second doped region from the first doped region. Further, the second insulating region may include a second distributed Bragg reflector.

In some embodiments, the semiconductor structure may include a first tunnel junction configured to electrically isolate the first nanostructure from a first source region and a second tunnel junction configured to electrically isolate the first nanostructure from a first drain region. Further, the diode may include a third tunnel junction configured to electrically isolate the second nanostructure from a second source region and a fourth tunnel junction configured to electrically isolate the second nanostructure from a second drain region. Additionally, or alternatively, the optical device may include a gate capacitor disposed between the gate region and the second doped region.

In some embodiments, the semiconductor structure may include a first gate region configured for controlling a current through the first doped region and the gate region may be a second gate region.

In another aspect, the present disclosure is directed to an embedded nanostructure including a nanostructure, where the nanostructure may be configured to be electrically isolated by a material layer. In some embodiments, the material layer may include a region of material, the entirety of the nanostructure, and a plurality of tunnel junctions configured to isolate the nanostructure from the region of material. Further, the region of material may be silicon. Additionally, or alternatively, the embedded nanostructure may include energy levels configured to control the flow of a plurality of particles through a single electron transistor device.

In some embodiments, the embedded nanostructure may be configured as an active region for light emission of a laser device, where the laser device further may include a second gate electrode configured to be reflective and at least partially transparent and a reflective surface. Further, a single electron transistor may include the embedded nanostructure. Additionally, or alternatively, a laser device may include the embedded nanostructure, where the embedded nanostructure may be configured as an active region for light emission of the laser device. In some embodiments, the laser device may include a second gate electrode configured to be reflective and at least partially transparent and a reflective surface.

In another aspect, the present disclosure is directed to a stacked structure that may include a doped region including a source region and drain region, a nanostructure as a dopant of the doped region, a substrate region, and an insulating region disposed between the doped region and the substrate region, where the insulating region may be configured to insulate the doped region from the substrate region. In some embodiments, the source region may be proximate a first side of the doped region, where the drain region may be proximate a second side of the doped region and particles may be configured to flow laterally between the drain region and the source region.

In some embodiments, the source region may be proximate a top of the doped region, the drain region may be proximate a bottom of the doped region, and particles may be configured to flow vertically between the drain region and the source region. Further, the stacked structure may include a plurality of doped regions, where each doped region of the plurality of doped regions may be configured to be a channel of a transistor of a plurality of transistors.

In another aspect, the present disclosure is directed to a method of manufacturing a semiconductor device, the method including providing a semiconductor wafer including a doped region, a substrate region, and an insulating region disposed between the doped region and the substrate region, where the insulating region may be configured to insulate the doped region from the substrate region. Further, the method may include forming a source region on the doped region and forming a drain region on the doped region, where the doped region includes (i) a nanostructure as a dopant of the doped region, (ii) a first tunnel junction configured to electrically isolate the nanostructure from the source region, and (iii) a second tunnel junction configured to electrically isolate the nanostructure from the drain region.

In some embodiments, the method may include forming an oxide region on the doped region and forming a gate region on the oxide region. Further, the doped region may be a first doped region, the nanostructure may be a first nanostructure, the source region may be a first source region, the drain region may be a first drain region, and the insulating region may be a first insulating region. Additionally, or alternatively, the semiconductor wafer may include a second doped region including (i) a second nanostructure as a dopant of the second doped region, (ii) a third tunnel junction configured to electrically isolate the second nanostructure from a second source region, and (iii) a fourth tunnel junction configured to electrically isolate the second nanostructure from a second drain region and a second insulating region disposed between the first doped region and the second doped region, where the second insulating region may be configured to insulate the first doped region from the second doped region.

In some embodiments, the method may include forming the second source region on the second doped region and forming the second drain region on the second doped region. Further, the method may include forming a gate region on the first doped region and the second doped region. Additionally, or alternatively, the method may include forming a first gate region on the first doped region and forming a second gate region on the second doped region, where the second gate region may include a first distributed Bragg reflector, the second insulating region may include a second distributed Bragg reflector, and the second doped region may be configured to emit light.

The features, functions, and advantages that have been discussed may be achieved independently in various embodiments of the present disclosure or may be combined with yet other embodiments, further details of which may be seen with reference to the following description and drawings.

### BRIEF DESCRIPTION OF THE DRAWINGS

Having thus described embodiments of the disclosure in general terms, reference will now be made to the accompanying drawings, wherein:

FIG. 1 schematically depicts a block diagram for a semiconductor device, in accordance with an embodiment of the present disclosure;

FIG. 2 schematically depicts a block diagram for an embedded nanostructure, in accordance with an embodiment of the present disclosure;

FIG. 3A schematically depicts a configuration of a lateral stacked structure, in accordance with an embodiment of the present disclosure;

FIG. 3B schematically depicts a configuration of a vertical stacked structure, in accordance with an embodiment of the present disclosure;

FIG. 4 schematically depicts a configuration of stacked gate-all-around semiconductor devices, in accordance with an embodiment of the disclosure;

FIG. 5 schematically depicts a configuration of an optical device, in accordance with an embodiment of the present disclosure;

FIG. 6 schematically depicts a method of manufacturing a lateral semiconductor device, in accordance with an embodiment of the disclosure;

FIG. 7 schematically depicts a method of manufacturing a top gate semiconductor device, in accordance with an embodiment of the disclosure;

FIG. 8 schematically depicts a method of manufacturing a gate-all-around semiconductor device, in accordance with an embodiment of the disclosure;

FIG. 9 schematically depicts a method of manufacturing two parallel lateral semiconductor devices with a common vertical gate, in accordance with an embodiment of the disclosure;

FIG. 10 schematically depicts a method of manufacturing two parallel vertical semiconductor devices with a common vertical gate; and

FIG. 11 illustrates a method of manufacturing a nanomaterial-based semiconductor device, in accordance with an embodiment of the disclosure.

### DETAILED DESCRIPTION OF EMBODIMENTS

Embodiments of the present disclosure will now be described more fully hereinafter with reference to the accompanying drawings, in which some, but not all, embodiments of the disclosure are shown. Indeed, the disclosure may be embodied in many different forms and should not be construed as limited to the embodiments set forth herein; rather, these embodiments are provided so that this disclosure will satisfy applicable legal requirements. Where possible, any terms expressed in the singular form herein are meant to also include the plural form and vice versa, unless explicitly stated otherwise. Also, as used herein, the term “a” and/or “an” shall mean “one or more,” even though the phrase “one or more” is also used herein. Further, as used herein, the article “the” is intended to include one or more items referenced in connection with the article “the” and may be used interchangeably with “the one or more. ” Furthermore, as used herein, the term “set” is intended to include one or more items (e.g., related items, unrelated items, a combination of related and unrelated items, etc.), and may be used interchangeably with “one or more. ” Where only one item is intended, the phrase “only one” or similar language is used. Also, as used herein, the terms “has,” “have,” “having,” or the like are intended to be open-ended terms. Furthermore, when it is said herein that something is “based on” something else, it may be based on one or more other things as well. In other words, unless expressly indicated otherwise, as used herein “based on” means “based at least in part on” or “based at least partially on. ” Also, as used herein, the term “or” is intended to be inclusive when used in a series and may be used interchangeably with “and/or,” unless explicitly stated otherwise (e.g., if used in combination with “either” or “only one of”). As used herein, terms such as “top,” “about,” “around,” and/or the like are used for explanatory purposes in the examples provided below to describe the relative position of components or portions of components. As used herein, the terms “substantially” and “approximately” refer to tolerances within manufacturing and/or engineering standards. Like numbers refer to like elements throughout. No element, act, or instruction used herein should be construed as critical or essential unless explicitly described as such.

As noted, there exists a need in the electronics industry for electronic devices with lower-power consumption and smaller device size. To meet these demands, new devices, and improvements to current devices are being developed.

The present disclosure is directed to nanomaterial-based semiconductor structures (e.g., semiconductor devices) and methods of manufacturing such semiconductor structures. Integration of nanostructures (e.g., organic quantum dots (QDs), inorganic QDs, fullerenes, and/or III-V (3-5) semiconductor materials) in a semiconductor layer may reduce the size of the semiconductor devices and may lower the applied voltage, thereby reducing heating of the structure. Further, the solution may simplify the manufacturing process by eliminating the need to dope the semiconductor layer and may reduce the size of the semiconductor devices. Moreover, embedding the nanostructures in the semiconductor layer may enable precise control of the doping of the semiconductor layer.

The nanomaterial-based semiconductor structures may be implemented in any processing circuitry. Such processing circuitry may comprise software, hardware such as an application specific integrated circuit (ASIC), or a combination thereof. Other non-limiting examples of the processing circuitry include an Integrated Circuit (IC) chip, a Central Processing Unit (CPU), a Graphics Processing Unit (GPU), a microprocessor, a Field Programmable Gate Array (FPGA), a collection of logic gates or transistors, resistors, capacitors, inductors, diodes, or the like. Some or all of the processing circuitry may be provided on a Printed Circuit Board (PCB) or collection of PCBs. It should be appreciated that any appropriate type of electrical component or collection of electrical components may be suitable for inclusion in the processing circuitry.

The nanomaterial-based semiconductor structures may include any semiconductor device such as transistor(s), vertical stacked structure(s), single-electron transistors (SETs), multi-SET stacked devices, diodes (e.g., photodiodes), lasers with transparent layers, and distributed Bragg reflector layer(s) etc.

As will be appreciated by one of ordinary skill in the art in view of the present disclosure, the presence and the properties of nanostructures may provide a material gain which may allow a reduction in the size of the semiconductor devices and may allow manufacturing of semiconductor devices in which no further doping is needed. In some embodiments, the size of the semiconductor devices may be limited by just lithography, which may allow scaling of the semiconductor devices. Additionally, or alternatively, embodiments of the present disclosure may enable an increase in the density of nanomaterial-based semiconductor devices in designed circuits, thereby enabling higher circuit performance.

In some embodiments, the doped semiconductor layer created by the incorporation of the nanostructures may enable integration of the nanomaterial-based semiconductor device into any semiconductor device. Further, the nanomaterial-based semiconductor devices may allow the use any CMOS conventional manufacturing techniques. In some embodiments, the resulting volume ratio of the gain material to the semiconductor thin layer is very high, which may enhance the power efficiency of the semiconductor device. Some embodiments of the present disclosure provide efficient and economical methods and mechanisms for manufacturing nanomaterial-based semiconductor devices and thereby provide improvements to the field of electronics.

Since in the structure of the present disclosure the dopants may be in the semiconductor layer, the structure may be implemented as a channel to set a metal-based transistor as described further below. In some embodiments, the nanomaterial-based semiconductor devices may be a transistor.

At a basic level, a transistor may include three terminals and may be designed such that a voltage or current applied to one terminal may control the flow of current between the other two terminals (e.g., a source and/or a drain). Some embodiments of configurations of the transistor s may include side-by-side configurations of the source and the drain, top gate, central gate and/or surrounding gate configurations, as well as multi-transistor stacked devices. Embodiments of the present disclosure may optionally be configured as laser sources with reflecting layers (e.g., a distributed Bragg reflector).

Using the semiconductor layer with embedded nanostructures may enable a reduction in the dimensions of the transistor devices and may make their fabrication more accurate. Disclosed methods may yield various configurations of the transistor devices, for various uses. Disclosed transistor devices may reduce power consumption and heat dissipation—improving the ability to scale up electronic circuits in which transistors are used (e.g., to switch current flows). Disclosed transistor configurations may have smaller transistors which may enable more calculations with less energy and less heat, and moreover, smaller transistors may enable an increase in the density of transistors in designed circuits, thereby enabling higher calculations performance.

Disclosed transistor devices may include a nanomaterial gain (e.g., comprising quantum dots) embedded in thin semiconductor layers - reaching a very high-volume ratio of the gain material to the semiconductor thin layer and enhancing the power efficiency of the transistor devices. Disclosed transistors may be smaller, require lower voltages and may generate less heat than conventional transistors. Disclosed transistor devices may also be manufactured more accurately, as the nanomaterial gain may be manufactured in the requited regions in advance (e.g., quantum dots embedded in silicon), rather than using conventional doping processes which require growth. For example, a silicon matrix may be prepared including specific regions for nanostructures to be embedded (e.g., spherical indium arsenide (InAs) nanocrystals fully embedded by silicon with ˜50 nm Si cap). Further, addition of dopants may be time consuming and may yield larger devices. Replacing the doping stage by using embedded nanomaterials may also enable utilizing memory effects within the transistors (e.g., negative U potential QDs characterized by a voltage-controlled hysteresis), fabricating vertical transistors, and manufacturing metal-based transistors that utilize tunneling channels provided by the nanomaterials.

Further, a transistor may include a nanostructure (e.g., a quantum dot, an artificial atom, a metallic island, and/or the like) that may reside in a doped region (e.g., from self-assembly growth and/or growth at specific regions from patterning methods, such as pillar patterning) that may be isolated from other elements of the transistor (e.g., a source and/or a drain) by at least two tunnel junctions. In other words, tunnel junctions may be configured to confine charge within the nanostructure. As will be appreciated by one of ordinary skill in the art in view of the present disclosure, tunnel junctions may be a barrier preventing the transmission of particles (e.g., an electron) classically, but, due to quantum mechanical effects, permit the particles to quantum mechanically “tunnel”through the tunnel junctions. Additionally, or alternatively, an electron may require an amount of energy to tunnel through the tunnel junction.

Single electron transistors (SETs) are one such device that is receiving interest due to its low power consumption, low heat generation, high sensitivity, and small size. Thus, enabling a high density for an array of SET devices. In some embodiments, a SET, in an operational state, may control the transport of a single and/or a small number of particles (e.g., electrons). In some embodiments, the transmission of particles may be controlled through the Coulomb blockade, where a certain bias may be required to induce tunneling across a nanostructure in a SET. For example, a SET may include a gate, a source, and a drain with a bias voltage between the source and the drain of zero and a gate voltage of zero. In this case, the energy of a particle may be insufficient to overcome the Coulomb blockade and may be prevented from tunneling through a tunnel junction to a nanostructure. Said differently, a current may not flow through the SET device. In some embodiments, the bias voltage between the source and a drain may increase (e.g., the bias voltage increases to e/C, where e is the charge of an electron and C is the self-capacitance of the nanostructure). Further, the increase in the bias voltage may increase the energy of a particle, where the increased energy of the particle may be sufficient (e.g., the particle energy reaches a Coulomb energy of e²/2C) to enable tunneling through the tunnel junction.

Additionally, or alternatively, the voltage of the gate may be increased which may influence the tunneling of a particle. In some embodiments, applying a voltage to the gate may shift the Fermi energy levels of the nanostructure. For example, applying a positive gate voltage (e.g., V_{G}>0) may lower the Fermi energy levels of the nanostructure and/or applying a negative gate voltage (e.g., V_{G}<0) may increase the Fermi energy levels of the nanostructure. As will be appreciated by one of ordinary skill in the art in view of the present disclosure, adjusting the gate voltage may shift the Fermi energy levels of the nanostructure which may allow control of the Coulomb blockade, thus allowing control of a transfer of a particle to and from the nanostructure and thereby allowing control of the current.

In some embodiments, manufacturing such nanostructure-based designs that operate at room temperature requires the use of complex techniques that are unsuitable for mass production in electronic devices. In some embodiments, a nanomaterial-based semiconductor device may have strict size constraints (e.g., less than 5 nanometers (nm)) on a nanostructure contained in the semiconductor device for operation at room temperature. In some embodiments, the nanostructure contained in a semiconductor device may be 1 nm in size (e.g., an organic QD and/or molecule). Additionally, or alternatively, the semiconductor device may require the thermal energy in the nanostructure to be below an energy threshold (e.g., k_{B}*T<<e²/2C, where k_{B} is Boltzmann's constant and T is the temperature) to control the current through the nanostructure. As will be appreciated by one of ordinary skill in the art in view of the present disclosure, a capacitance may have a dependence on a dimensionality of a device and/or nanostructure (e.g., C=ϵₒ*ϵᵣ*A/d, where ϵₒ is the vacuum permittivity, ϵᵣ is the dielectric constant of the material, A is the area, and d is the distance of separation) which may constrain the dimensionality of the device and/or nanostructure in order to operate at room temperature.

The present disclosure is directed to a nanomaterial-based semiconductor device that may include a region of semiconductor material (e.g., Si, Ge, GaAs, GaN, and/or the like) doped with nanostructures that may simplify manufacturing and may achieve a semiconductor device operable at room temperature. For room temperature operation, nanomaterial-based semiconductor devices based on semiconductor materials require pillar-patterning and other techniques to achieve a self-assembling quantum dot. Such techniques increase the complexity of manufacturing such that mass production for use in electronic devices is impractical.

In some embodiments, the nanomaterial-based semiconductor device may be manufactured from a wafer on substrate that may be created using techniques employed in the manufacture of semiconductor-based optical devices. Further, by using such a wafer including a region doped with nanostructures, the manufacturing of a nanomaterial-based semiconductor device may be simplified as compared to conventional semiconductor devices and conventional manufacturing methods that use other techniques to form nanostructures. This design technique may also be used to create a laser device that includes a diode incorporated with the semiconductor device. The nanomaterial-based semiconductor device and the diode may each include a doped region including nanostructures as dopants. In such devices, layers of the device (e.g., an insulating region, a gate region, and/or the like) may include distributed Bragg reflectors such that the doped region of the diode is configured to emit light. Additionally, or alternatively, by combining the semiconductor device and a diode in this manner, the overall size of the device may be reduced, and an interface between the electrical and optical domains may be simplified.

In some embodiments, the semiconductor device may include a doped region, a substrate region, and an insulating region disposed between the doped region and the substrate region. The doped region (e.g., a doped silicon region and/or an intrinsic semiconductor material doped with nanostructures) includes nanostructures (e.g., a quantum dots layer) as dopants and tunnel junctions that may be configured to electrically isolate individual nanostructures and/or groups of the nanostructures from a source region and/or a drain region. The insulating region (e.g., a silicon dioxide region, a dielectric material, and/or the like) may be configured to insulate the doped region from the substrate region (e.g., an intrinsic silicon region) to reduce parasitic effects and improve device performance. Further, the doped region, the substrate region, and/or the insulating region may be provided as a wafer on substrate. By using such a wafer including a region doped with nanostructures, the manufacturing of a nanomaterial-based semiconductor device may be simplified as compared to conventional nanomaterial-based semiconductor devices and conventional manufacturing methods that use other techniques to form individual nanostructures. Embodiments of the present disclosure may also include a gate region and a gate capacitor between the gate region and the doped region, where the gate region is configured for controlling a current through the doped region. In some embodiments, the semiconductor device may be a lateral transistor, a silicon-on-insulator-wafer-based transistor, a gate-all-around transistor, and/or a multi-channel transistor including multiple doped regions.

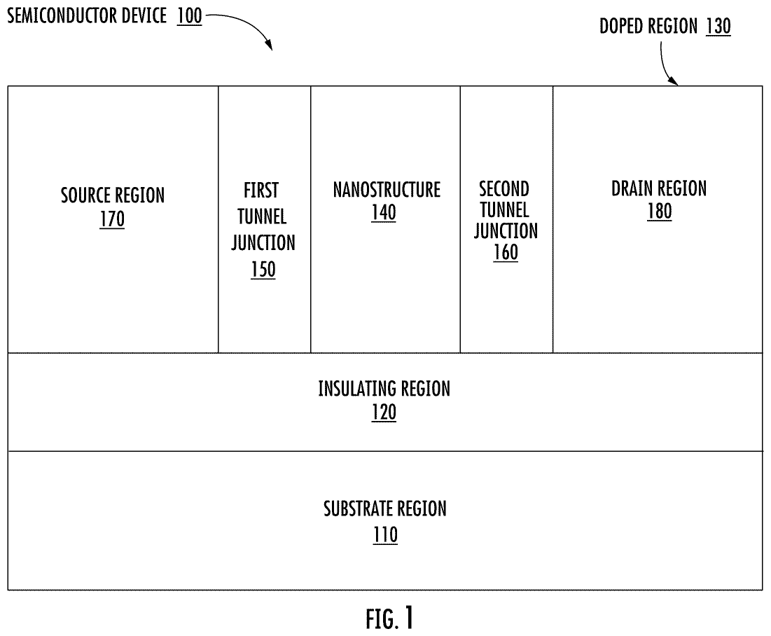

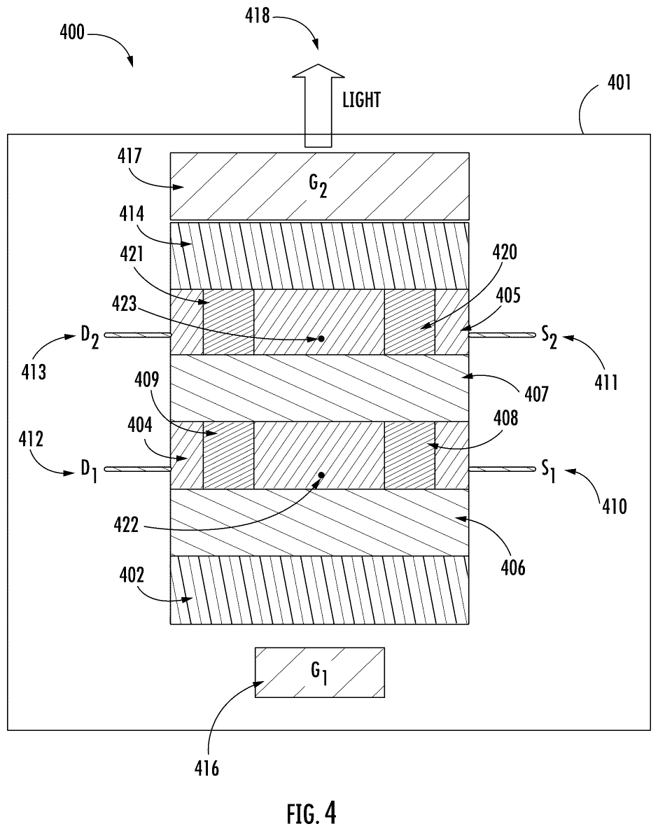

FIG. 1 schematically depicts a block diagram for a semiconductor device 100, in accordance with an embodiment of the present disclosure. In some embodiments, the semiconductor device 100 may include a doped region 130, a substrate region 110, and an insulating region 120 disposed between the doped region 130 and the substrate region 110, where the insulating region 120 is configured to insulate the doped region 130 from the substrate region 110. Further, the doped region 130 may include a nanostructure 140 as a dopant of the doped region, a first tunnel junction 150 configured to electrically isolate the nanostructure 140 from a source region 170, and/or a second tunnel junction 160 configured to electrically isolate the nanostructure from a drain region 180. In some embodiments, the semiconductor device 100 may be similar to, include elements similar to, and/or be manufactured in a manner similar to one or more of the semiconductor devices shown and described herein with respect to FIGS. 4-11.

In some embodiments, the doped region 130 may include a doped silicon region. For example, the doped region 130 may be similar to one or more of the doped regions shown and described herein with respect to FIGS. 4-11 Further, the nanostructure 140 may include a quantum dots layer. Additionally, or alternatively, the doped region 130 may include an intrinsic semiconductor material doped with the nanostructure 140. In some embodiments, the nanostructure 140 may have a largest dimension of 5 nanometers or less.

In some embodiments, the first tunnel junction 150 may include a first thickness between the nanostructure 140 and the source region 170 of 3 nanometers or less, and/or the second tunnel junction 160 may have a second thickness between the nanostructure 140 and/or the drain region 180 of 3 nanometers or less. Additionally, or alternatively, the substrate region 110 may include intrinsic silicon.

In some embodiments, the insulating region 120 may include silicon dioxide. Further, the insulating region 120 may include a dielectric material. Additionally, or alternatively, the source region 170 and/or the drain region 180 may be disposed on the doped region 130.

In some embodiments, the semiconductor device 100 may include a gate region configured for controlling a current through the doped region 130. Further, the semiconductor device 100 may include a gate capacitor disposed between the gate region and the doped region 130. Additionally, or alternatively, the gate capacitor may include an oxide region.

In some embodiments, the doped region 130 may be a first doped region, the nanostructure 140 may be a first nanostructure, the source region 170 may be a first source region, the drain region 180 may be a first drain region, the insulating region 120 may be a first insulating region, and the semiconductor device 100 may include a second doped region, a second insulating region disposed between the first doped region and the second doped region, where the second insulating region may be configured to insulate the first doped region from the second doped region. Further, the second doped region may include a second nanostructure as a dopant of the second doped region, a third tunnel junction configured to electrically isolate the second nanostructure from a second source region, and a fourth tunnel junction configured to electrically isolate the second nanostructure from a second drain region.

In some embodiments, the semiconductor device may include a gate region configured for controlling a current through the first doped region and the second doped region. Further, the semiconductor device 100 may include a first gate region configured for controlling a first current through the first doped region, a second gate region configured for controlling a second current through the second doped region, where the second gate region may include a first distributed Bragg reflector, and a gate capacitor disposed between the second gate region and the second doped region. Additionally, or alternatively, the second insulating region may include a second distributed Bragg reflector and/or the second doped region may be configured to emit light.

As will be appreciated by one of ordinary skill in the art in view of the present disclosure, the semiconductor device 100 may include additional embodiments, such as any single embodiment or any combination of embodiments described herein.

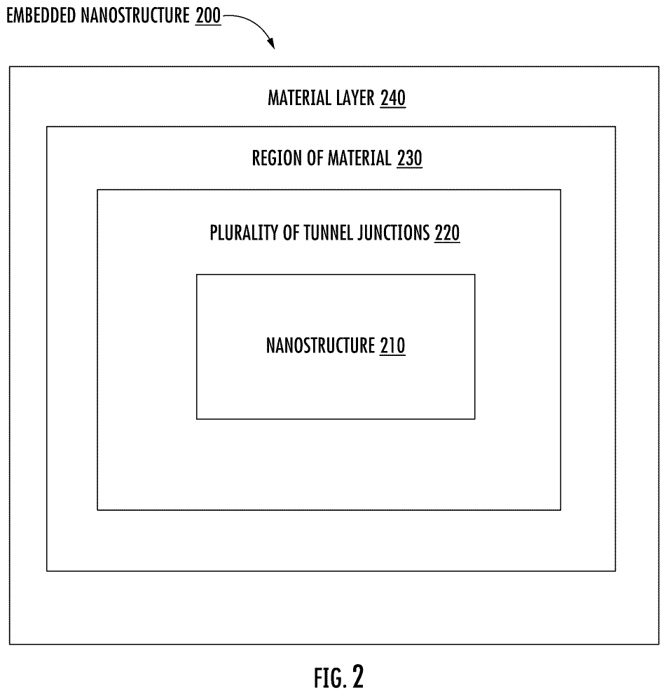

FIG. 2 schematically depicts a block diagram for an embedded nanostructure 200, in accordance with an embodiment of the present disclosure. In some embodiments, the embedded nanostructure 200 may include a nanostructure 210 and/or a material layer 240. Further, the nanostructure 210 may be configured to be electrically isolated by the material layer 240. Additionally, or alternatively, the material layer 240 may include a region of material 230, the entirety of the nanostructure 210, and a plurality of tunnel junctions 220 configured to isolate the nanostructure 210 from the region of material 230.

In some embodiments, the region of material 230 may be silicon. Additionally, or alternatively, the embedded nanostructure 210 may include energy levels configured to control the flow of a plurality of particles through a single electron transistor device.

In some embodiments, the embedded nanostructure 210 may be configured as an active region for light emission of a laser device. Further, the laser device may include a second gate electrode configured to be reflective and at least partially transparent, and a reflective surface. Additionally, or alternatively, a single electron transistor may include the embedded nanostructure 210.

As will be appreciated by one of ordinary skill in the art in view of the present disclosure, the embedded nanostructure 200 may include additional embodiments, such as any single embodiment or any combination of embodiments described herein.

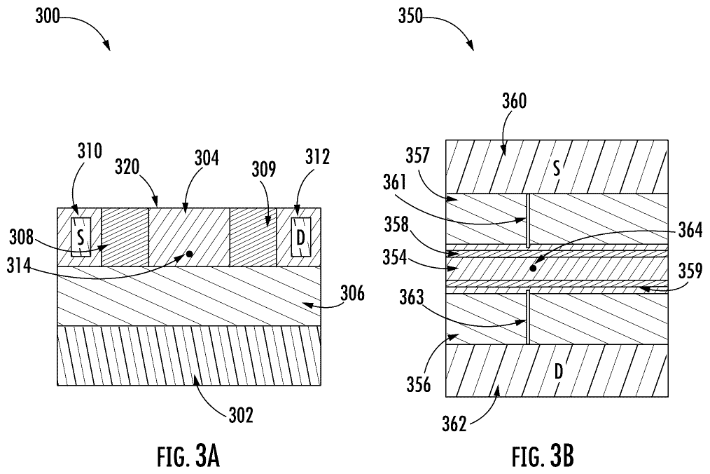

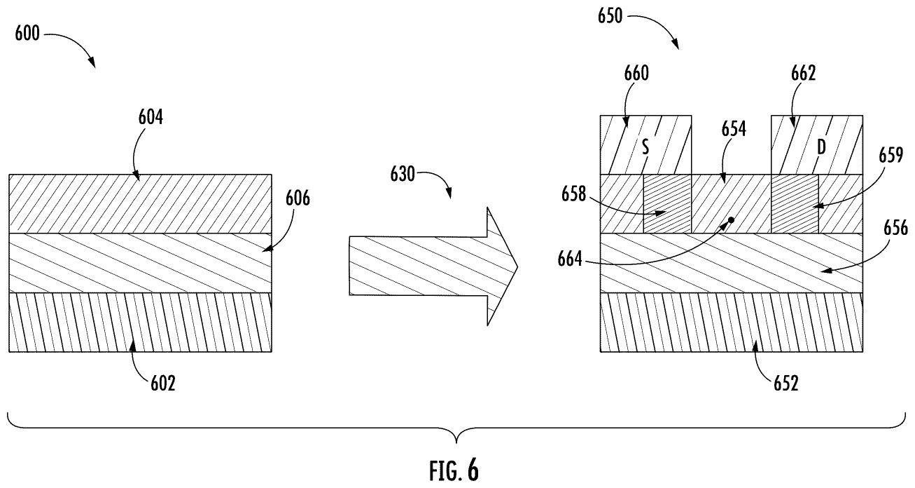

FIG. 3A schematically depicts a configuration of a lateral stacked structure 300, in accordance with an embodiment of the present disclosure. In some embodiments, creation of the lateral stacked structure 300 may be formed from a doped silicon stack (e.g., similar to the doped silicon stack 600 as shown and described herein with respect to FIG. 6) and may include a substrate region 302. Additionally, or alternatively, the lateral stacked structure 300 may include a doped region 304, where the doped region 304 may include a density of nanostructures (e.g., similar to the nanostructures 664 as shown and described herein with respect to FIG. 6) and a plurality of tunnel junctions. In some embodiments the doped region 304 may be configured as a channel 320 of a semiconductor device. In some embodiments, the density of nanostructures may include a nanostructure 314, and the plurality of tunnel junctions may include a first tunnel junction 308 and/or a second tunnel junction 309 (e.g., similar to the first tunnel junction 658 and the second tunnel junction 659 as shown and described herein with respect to FIG. 6). In some embodiments, the lateral stacked structure 300 may include an insulating region 306 (e.g., a layer of silicon dioxide, dielectric material, and/or the like). Further, and in some embodiments, the insulating region 306 may be proximate the substrate region 302 such that the insulating region 306 may lie directly on the substrate region 302. Additionally, or alternatively, the doped region 304 may be proximate the insulating region 306 such that the doped region 304 may lie directly on the insulating region 306. In some embodiments, the insulating region 306 isolates the doped region 304 from the substrate region 302.

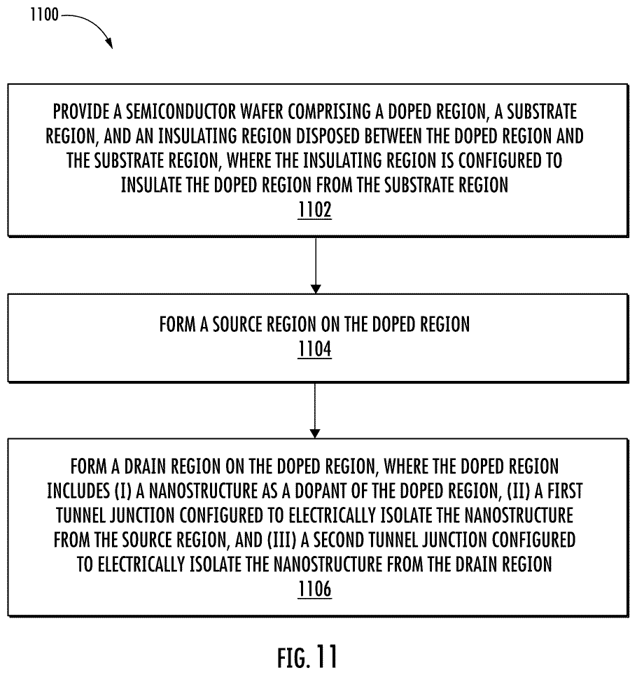

In some embodiments, the manufacturing of the lateral stacked structure 300 may include any combination of the manufacturing steps shown and described herein with respect to FIG. 11.

In some embodiments, the first tunnel junction 308 and the second tunnel junction 309 may be configured to isolate the nanostructure 314 of the doped region 304 from other parts of the lateral stacked structure 300. Further, the first tunnel junction 308 and the second tunnel junction 309 may be configured to allow particles (e.g., electrons) to tunnel through the first tunnel junction 308 and the second tunnel junction 309. Additionally, or alternatively, the first tunnel junction 308 and the second tunnel junction 309 may be configured to not allow particles to tunnel through the first tunnel junction 308 and the second tunnel junction 309. As will be appreciated by one of ordinary skill in the art in view of the present disclosure, the ability of a particle to tunnel through a tunnel barrier may be influenced by the energy of the particle in relation to the energy level of where the particle is tunneling.

In some embodiments, the doped region 304 may include a source region 310 and a drain region 312, and the source region 310 and the drain region 312 may be configured to have a bias voltage between one another. In some embodiments, under a structure dependent bias voltage of the source region 310 and the drain region 312, the lateral stacked structure 300 may be configured to enable a particle to tunnel through the first tunnel junction 308 and/or the second tunnel junction 309. Additionally, or alternatively, under a bias voltage of the source region 310 and the drain region 312 less than the structure dependent bias voltage of the source region 310 and the drain region 312, the lateral stacked structure 300 may be configured to enable a particle to not tunnel through the first tunnel junction 308 and/or the second tunnel junction 309. As will be appreciated by one of ordinary skill in the art in view of the present disclosure, controlling the bias voltages applied to the lateral stacked structure 300 may allow control of the transmission of a particle through the lateral stacked structure 300 which may control a current through the lateral stacked structure 300. Further, controlling the transmission of a particle through the lateral stacked structure 300 in such a manner may cause the current through the lateral stacked structure 300 to be quantized.

As will be appreciated by one of ordinary skill in the art in view of the present disclosure, the lateral stacked structure 300 may include additional embodiments, such as any single embodiment or any combination of embodiments described herein. Furthermore, the lateral stacked structure 300 may include other elements that are configured to control the barrier between a channel (e.g., a plurality of tunnel junctions and density of nanostructures between a source contact and drain contact) and the source region 310 and the drain region 312.

FIG. 3B schematically depicts a configuration of a vertical stacked structure 350, in accordance with an embodiment of the present disclosure. In some embodiments, creation of the vertical stacked structure 350 may be formed from a doped silicon stack (e.g., similar to the doped silicon stack 600 as shown and described herein with respect to FIG. 6). Additionally, or alternatively, the vertical stacked structure 350 may include a doped region 354, where the doped region 354 may include a density of nanostructures (e.g., similar to the nanostructures 664 as shown and described herein with respect to FIG. 6) and a plurality of tunnel junctions. In some embodiments, the density of nanostructures may include a nanostructure 364 and, in some embodiments, the plurality of tunnel junctions may include a first tunnel junction 358 and/or a second tunnel junction 359 (e.g., similar to the first tunnel junction 658 and the second tunnel junction 659 as shown and described herein with respect to FIG. 6). In some embodiments, the vertical stacked structure 350 may include a first insulating region 356 and/or second insulating region 357 (e.g., a layer of silicon dioxide, dielectric material, and/or the like). Additionally, or alternatively, the doped region 354 may be proximate the first insulating region 356 such that the doped region 354 may lie directly on the first insulating region 356. Further, the doped region 354 may be proximate the second insulating region 357 such that the doped region 354 may lie directly under the second insulating region 357. In some embodiments, the doped region 354 may include a source region 361 and a drain region 363.

In some embodiments, the manufacturing of the vertical stacked structure 350 may include any combination of the manufacturing steps shown and described herein with respect to FIG. 11.

In some embodiments, the first tunnel junction 358 and the second tunnel junction 359 may be configured to isolate the nanostructure 364 of the doped region 354 from other parts of the vertical stacked structure 350. Further, the first tunnel junction 358 and the second tunnel junction 359 may be configured to allow particles (e.g., electrons) to tunnel through the first tunnel junction 358 and the second tunnel junction 359. Additionally, or alternatively, the first tunnel junction 358 and the second tunnel junction 359 may be configured to not allow particles to tunnel through the first tunnel junction 358 and the second tunnel junction 359. As will be appreciated by one of ordinary skill in the art in view of the present disclosure, the ability of a particle to tunnel through a tunnel barrier may be influenced by the energy of the particle in relation to the energy level of where the particle is tunneling.

In some embodiments, a source contact 360 may be proximate the second insulating region 357 such that the source contact 360 may lie directly on the second insulating region 357. Further, a drain contact 362 may be proximate the first insulating region 356 such that the drain contact 362 may lie directly under the first insulating region 356. In some embodiments, the source contact 360 and the drain contact 362 may be configured to have a bias voltage between one another. In some embodiments, under a structure dependent bias voltage of the source contact 360 and the drain contact 362, the vertical stacked structure 350 may be configured to enable a particle to tunnel through the first tunnel junction 358 and/or the second tunnel junction 359. Additionally, or alternatively, under a bias voltage of the source contact 360 and the drain contact 362 less than the structure dependent bias voltage of the source contact 360 and the drain contact 362, the vertical stacked structure 350 may be configured to enable a particle to not tunnel through the first tunnel junction 358 and/or the second tunnel junction 359.

As will be appreciated by one of ordinary skill in the art in view of the present disclosure, controlling the bias voltages applied to the vertical stacked structure 350 may allow control of the transmission of a particle through the vertical stacked structure 350 which may control a current through the vertical stacked structure 350. Further, controlling the transmission of a particle through the vertical stacked structure 350 in such a manner may cause the current through the vertical stacked structure 350 to be quantized.

As will be appreciated by one of ordinary skill in the art in view of the present disclosure, the vertical stacked structure 350 may include additional embodiments, such as any single embodiment or any combination of embodiments described herein. Furthermore, the vertical stacked structure 350 may include other elements that are configured to control the barrier between a channel (e.g., a plurality of tunnel junctions and density of nanostructures between a source contact and drain contact) and the source contact 360 and the drain contact 362.

FIG. 4 schematically depicts a configuration of stacked gate-all-around semiconductor devices 400, in accordance with an embodiment of the present disclosure. In some embodiments, the stacked gate-all-around semiconductor devices 400 may be formed from a doped silicon stack (e.g., similar to the doped silicon stack 600 as shown and described herein with respect to FIG. 6) and may include a substrate region 402. Additionally, or alternatively, the stacked gate-all-around semiconductor devices 400 may include a first doped region 404, where the first doped region 404 may include a density of nanostructures (e.g., similar to the nanostructures 664 as shown and described herein with respect to FIG. 6) and a first plurality of tunnel junctions. In some embodiments, the density of nanostructures may include a first nanostructure 422 and, the first plurality of tunnel junctions may include a first tunnel junction 408 and/or a second tunnel junction 409 (e.g., similar to the first tunnel junction 658 and the second tunnel junction 659 as shown and described herein with respect to FIG. 6). In some embodiments, the stacked gate-all-around semiconductor devices 400 may include a first insulating region 406 (e.g., a layer of silicon dioxide, dielectric material, and/or the like). Additionally, or alternatively, the stacked gate-all-around semiconductor devices 400 may include a second insulating region 407 (e.g., a layer of silicon dioxide, dielectric material, and/or the like).

In some embodiments, the stacked gate-all-around semiconductor devices 400 may include a second doped region 405, where the second doped region 405 may include a density of nanostructures and a second plurality of tunnel junctions. In some embodiments, the density of nanostructures may include a second nanostructure 423 and, the second plurality of tunnel junctions may include a third tunnel junction 420 and/or a fourth tunnel junction 421 (e.g., similar to the first tunnel junction 658 and the second tunnel junction 659 as shown and described herein with respect to FIG. 6). Further, the stacked gate-all-around semiconductor devices 400 may include a first source contact 410 and a first drain contact 412 proximate the first doped region 404, where, in an operative state, the first source contact 410 and the first drain contact 412 may be configured to be coupled to the nanostructures of the first doped region 404. Additionally, or alternatively, the stacked gate-all-around semiconductor devices 400 may include a second source contact 411 and a second drain contact 413 proximate the second doped region 405, where, in an operative state, the second source contact 411 and the second drain contact 413 may be configured to be coupled to the nanostructures of the second doped region 405.

In some embodiments, the stacked gate-all-around semiconductor devices 400 may include a first gate region 416 (e.g., a gate-all-around region) which may be proximate the entirety of the stacked gate-all-around semiconductor devices 400. As will be appreciated by one of ordinary skill in the art in view of the present disclosure, the first gate region 416 is depicted in FIG. 4 as being below the stacked gate-all-around semiconductor devices 400 due to the two-dimensional nature of FIG. 4. Further, the stacked gate-all-around semiconductor devices 400 may include a second gate region 417. Additionally, or alternatively, the stacked gate-all-around semiconductor devices 400 may include an oxide region 414, where the oxide region 414 may be configured to insulate the stacked gate-all-around semiconductor devices 400 from the second gate region 417. In other words, the stacked gate-all-around semiconductor devices 400 may be manufactured from a doped silicon stack with a first source contact 410 and a first drain contact 412 deposited proximate a first doped region 404, a second source contact 411 and second drain contact 413 deposited proximate a second doped region 405, and a first gate region 416 which may be deposited proximate the entirety of the stacked gate-all-around semiconductor devices 400.

In some embodiments, the plurality of tunnel junctions of the first doped region 404 and/or the second doped region 405 may be configured to isolate at least one nanostructure of the density of nanostructures of the first doped region 404 and/or second doped region 405 from other parts of the stacked gate-all-around semiconductor devices 400. Further, the plurality of tunnel junctions of the first doped region 404 and/or second doped region 405 may be configured to allow particles (e.g., electrons) to tunnel through the plurality of tunnel junctions of the first doped region 404 and/or second doped region 405. Additionally, or alternatively, the plurality of tunnel junctions of the first doped region 404 and/or the second doped region 405 may be configured to not allow particles to tunnel through the plurality of tunnel junctions of the first doped region 404 and/or the second doped region 405. As will be appreciated by one of ordinary skill in the art in view of the present disclosure, the ability of a particle to tunnel through a tunnel barrier may be influenced by the energy of the particle in relation to the energy level of where the particle is tunneling.

In some embodiments, the first source contact 410 and the first drain contact 412 may be configured to have a bias voltage between one another. Additionally, or alternatively, under a structure dependent bias voltage of the first source contact 410 and first drain contact 412, the stacked gate-all-around semiconductor devices 400 may be configured to enable a particle to tunnel through at least one tunnel junction of the plurality of tunnel junctions of the first doped region 404. Further, under a bias voltage of the first source contact 410 and the first drain contact 412 less than the structure dependent bias voltage of the first source contact 410 and the first drain contact 412, the stacked gate-all-around semiconductor devices 400 may be configured to enable a particle to not tunnel through the one or more tunnel junctions of the plurality of tunnel junctions of the first doped region 404.

In some embodiments, the second source contact 411 and the second drain contact 413 may be configured to have a bias voltage between one another. Additionally, or alternatively, under a structure dependent bias voltage of the second source contact 411 and second drain contact 413, the stacked gate-all-around semiconductor devices 400 may be configured to enable a particle to tunnel through at least one tunnel junction of the plurality of tunnel junctions of the second doped region 405. Further, under a bias voltage of the second source contact 411 and the second drain contact 413 less than the structure dependent bias voltage of the second source contact 411 and the second drain contact 413, the stacked gate-all-around semiconductor devices 400 may be configured to enable a particle to not tunnel through the one or more tunnel junctions of the plurality of tunnel junctions of the second doped region 405. As will be appreciated by one of ordinary skill in the art in view of the present disclosure, controlling the bias voltages applied to the stacked gate-all-around semiconductor devices 400 may allow control of the transmission of a particle through the stacked gate-all-around semiconductor devices 400 which may control a current through the stacked gate-all-around semiconductor devices 400.

In some embodiments, a voltage may be applied to the first gate region 416. Additionally, or alternatively, the first gate region 416 may be configured to transfer energy to the first doped region 404 and/or the second doped region 405 (e.g., through capacitive coupling). In some embodiments, the first gate region 416 may be configured to shift the energy levels of at least one nanostructure of the density of nanostructure via adjusting the applied voltage to the first gate region 416. Further, by shifting the energy levels, tunneling of a particle through at least one tunnel junction of the first and/or second plurality of tunnel junctions may occur. Additionally, or alternatively, by shifting the energy levels, tunneling of a particle through at least one tunnel junction of the first and/or second plurality of tunnel junctions may not occur.

In some embodiments, controlling the transmission of a particle through the stacked gate-all-around semiconductor devices 400 in such a manner may cause the current through the stacked gate-all-around semiconductor devices 400 to be quantized. As will be appreciated by one of ordinary skill in the art in view of the present disclosure, transmission of a particle and/or an electron through the stacked gate-all-around semiconductor devices 400 may be controlled by adjusting the bias voltage across the first source contact 410 and the first drain contact 412 and/or the second source contact 411 and the second drain contact 413, by adjusting the voltage applied to the first gate region 416, and/or a combination of both.

In some embodiments, the stacked gate-all-around semiconductor devices 400 may be configured as a laser device 401 for use in emitting light 418. For example, the second gate region 417 may be modified such that it serves as a reflective material (e.g., a distributed Bragg reflector). Additionally, or alternatively, the second insulating region 407 may be modified such that it serves as a reflective material (e.g., a distributed Bragg reflector). In some embodiments, one of a modified gate region or modified second insulating region may be configured to serve as a mirror and may include metal. Further, the other region not configured to serve as a mirror may be configured as a distributed Bragg reflector emitting light 418. As will be appreciated by one of ordinary skill in the art in view of the present disclosure, one could engineer a bottom or top emitter laser with such a configuration.

In some embodiments, the second doped region 405 may be configured to serve as an active region for use in emitting light 418. Further, in some embodiments, a combination of a reflective gate region, a reflective second insulating region, and/or a second doped region as an active region may form a diode. In some embodiments, the diode may be configured for use in emitting light 418. In this regard, an optical device may include the stacked gate-all-around semiconductor devices 400 where the first doped region 404 is a portion of a semiconductor structure (e.g., a transistor) and the second doped region 405 is a portion of a diode.

As will be appreciated by one of ordinary skill in the art in view of the present disclosure, the configuration of the stacked gate-all-around semiconductor devices 400 may include additional embodiments, such as any single embodiment or any combination of embodiments described herein. Although FIG. 4 shows example steps of the method, in some embodiments, the method may include additional steps, fewer steps, different steps, or differently arranged steps than those depicted in FIG. 4 Furthermore, the stacked gate-all-around semiconductor devices 400 may include other elements that are configured to control the barrier between a channel (e.g., a plurality of tunnel junctions and density of nanostructures between a source contact and drain contact) and a source contact and a drain contact.

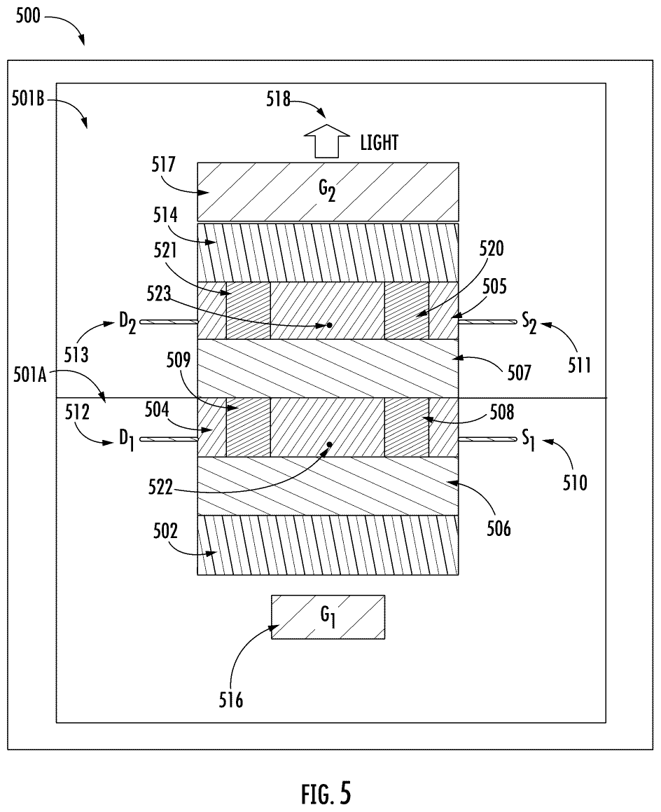

FIG. 5 schematically depicts a configuration of an optical device 500, in accordance with an embodiment of the present disclosure. In some embodiments, the optical device 500 may be formed from a semiconductor device 501A and/or a diode 501B. In some embodiments, the semiconductor device 501A and/or the diode 501B may be formed from a doped silicon stack (e.g., similar to the doped silicon stack 600 as shown and described herein with respect to FIG. 6).

The semiconductor device 501A and may include a substrate region 502. Additionally, or alternatively, the semiconductor device 501A may include a first doped region 504, where the first doped region 504 may include a density of nanostructures (e.g., similar to the nanostructures 664 as shown and described herein with respect to FIG. 6) and a first plurality of tunnel junctions. In some embodiments, the density of nanostructures may include a first nanostructure 522 and, the first plurality of tunnel junctions may include a first tunnel junction 508 and/or a second tunnel junction 509 (e.g., similar to the first tunnel junction 658 and the second tunnel junction 659 as shown and described herein with respect to FIG. 6). In some embodiments, the semiconductor device 501A may include a first insulating region 506 (e.g., a layer of silicon dioxide, dielectric material, and/or the like). Further, the semiconductor device 501A may include a first source contact 510 and a first drain contact 512 proximate the first doped region 504, where, in an operative state, the first source contact 510 and the first drain contact 512 may be configured to be coupled to the nanostructures of the first doped region 504.

The diode 501B may include a second doped region 505, where the second doped region 505 may include a density of nanostructures (e.g., similar to the nanostructures 664 as shown and described herein with respect to FIG. 6) and a second plurality of tunnel junctions. In some embodiments, the density of nanostructures may include a second nanostructure 523 and, the second plurality of tunnel junctions may include a third tunnel junction 520 and/or a fourth tunnel junction 521 (e.g., similar to the first tunnel junction 658 and the second tunnel junction 659 as shown and described herein with respect to FIG. 6). In some embodiments, the diode 501B may include a second insulating region 507 (e.g., a layer of silicon dioxide, dielectric material, and/or the like). Further, the diode 501B may include a second source contact 511 and a second drain contact 513 proximate the second doped region 505, where, in an operative state, the second source contact 511 and the second drain contact 513 may be configured to be coupled to the nanostructures of the second doped region 505.

In some embodiments, the optical device 500 may include a first gate region 516 (e.g., a gate-all-around region) which may be proximate the entirety of the optical device 500. As will be appreciated by one of ordinary skill in the art in view of the present disclosure, the first gate region 516 is depicted in FIG. 5 as being below the optical device 500 due to the two-dimensional nature of FIG. 5. Further, the optical device 500 may include a second gate region 517. Additionally, or alternatively, the optical device 500 may include an oxide region 514, where the oxide region 514 may be configured to insulate the diode 501B from the second gate region 517.

In some embodiments, the plurality of tunnel junctions of the first doped region 504 and/or the second doped region 505 may be configured to isolate at least one nanostructure of the density of nanostructures of the first doped region 504 and/or second doped region 505 from other parts of the optical device 500. Further, the plurality of tunnel junctions of the first doped region 504 and/or second doped region 505 may be configured to allow particles (e.g., electrons) to tunnel through the plurality of tunnel junctions of the first doped region 504 and/or second doped region 505. Additionally, or alternatively, the plurality of tunnel junctions of the first doped region 504 and/or the second doped region 505 may be configured to not allow particles to tunnel through the plurality of tunnel junctions of the first doped region 504 and/or the second doped region 505. As will be appreciated by one of ordinary skill in the art in view of the present disclosure, the ability of a particle to tunnel through a tunnel barrier may be influenced by the energy of the particle in relation to the energy level of where the particle is tunneling.

In some embodiments, the first source contact 510 and the first drain contact 512 may be configured to have a bias voltage between one another. Additionally, or alternatively, under a structure dependent bias voltage of the first source contact 510 and first drain contact 512, the semiconductor device 501A may be configured to enable a particle to tunnel through at least one tunnel junction of the plurality of tunnel junctions of the first doped region 504. Further, under a bias voltage of the first source contact 510 and the first drain contact 512 less than the structure dependent bias voltage of the first source contact 510 and the first drain contact 512, the semiconductor device 501A may be configured to enable a particle to not tunnel through the one or more tunnel junctions of the plurality of tunnel junctions of the first doped region 504.

In some embodiments, the second source contact 511 and the second drain contact 513 may be configured to have a bias voltage between one another. Additionally, or alternatively, under a structure dependent bias voltage of the second source contact 511 and second drain contact 513, the diode 501B may be configured to enable a particle to tunnel through at least one tunnel junction of the plurality of tunnel junctions of the second doped region 505. Further, under a bias voltage of the second source contact 511 and the second drain contact 513 less than the structure dependent bias voltage of the second source contact 511 and the second drain contact 513, the diode 501B may be configured to enable a particle to not tunnel through the one or more tunnel junctions of the plurality of tunnel junctions of the second doped region 505. As will be appreciated by one of ordinary skill in the art in view of the present disclosure, controlling the bias voltages applied to the optical device 500 may allow control of the transmission of a particle through the optical device 500 which may control a current through the optical device 500.

In some embodiments, a voltage may be applied to the first gate region 516. Additionally, or alternatively, the first gate region 516 may be configured to transfer energy to the first doped region 504 and/or the second doped region 505 (e.g., through capacitive coupling). In some embodiments, the first gate region 516 may be configured to shift the energy levels of at least one nanostructure of the density of nanostructure via adjusting the applied voltage to the first gate region 516. Further, by shifting the energy levels, tunneling of a particle through at least one tunnel junction of the first and/or second plurality of tunnel junctions may occur. Additionally, or alternatively, by shifting the energy levels, tunneling of a particle through at least one tunnel junction of the first and/or second plurality of tunnel junctions may not occur.

In some embodiments, controlling the transmission of a particle through the optical device 500 in such a manner may cause the current through the optical device 500 to be quantized. As will be appreciated by one of ordinary skill in the art in view of the present disclosure, transmission of a particle and/or an electron through the optical device 500 may be controlled by adjusting the bias voltage across the first source contact 510 and the first drain contact 512 and/or the second source contact 511 and the second drain contact 513, by adjusting the voltage applied to the first gate region 516, and/or a combination of both.

In some embodiments, the optical device 500 may be configured as a laser device for use in emitting light 518. For example, the second gate region 517 may be modified such that it serves as a reflective material (e.g., a distributed Bragg reflector). Additionally, or alternatively, the second insulating region 507 may be modified such that it serves as a reflective material (e.g., a distributed Bragg reflector). In some embodiments, one of a modified gate region or modified second insulating region may be configured to serve as a mirror and may include metal. Further, the other region not configured to serve as a mirror may be configured as a distributed Bragg reflector emitting light 518. As will be appreciated by one of ordinary skill in the art in view of the present disclosure, one could engineer a bottom or top emitter laser with such a configuration. In some embodiments, the second doped region 505 may be configured to serve as an active region for use in emitting light 518. In some embodiments, the diode 501B may be configured for use in emitting light 518.

As will be appreciated by one of ordinary skill in the art in view of the present disclosure, the configuration of the optical device 500 may include additional embodiments, such as any single embodiment or any combination of embodiments described herein. Furthermore, the optical device 500 may include other elements that are configured to control the barrier between a channel (e.g., a plurality of tunnel junctions and density of nanostructures between a source contact and drain contact) and a source contact and a drain contact.

FIG. 6 schematically depicts a method of manufacturing a lateral semiconductor device 650, in accordance with an embodiment of the present disclosure. In some embodiments, creation of the semiconductor device 650 may include a doped silicon stack 600 comprising a substrate region 602 (e.g., a layer of silicon), a doped region 604 (e.g., a layer of silicon with embedded nanostructures), and an insulating region 606 (e.g., a layer of silicon dioxide, dielectric material, and/or the like). Further, and in some embodiments, the insulating region 606 may be proximate the substrate region 602 such that the insulating region 606 may lie directly on the substrate region 602. Additionally, or alternatively, the doped region 604 may be proximate the insulating region 606 such that the doped region 604 may lie directly on the insulating region 606. In some embodiments, the insulating region 606 isolates the doped region 604 from the substrate region 602.

In some embodiments, the doped region 604 may include silicon containing a density of nanostructures 664 (e.g., quantum dots) and a plurality of tunnel junctions. In some embodiments, the manufacturing of the doped silicon stack 600 may include any combination of the manufacturing steps shown and described herein with respect to FIG. 11. Additionally, or alternatively, the doped silicon stack 600 may undergo manufacturing steps 630, where the manufacturing steps 630 include any combination of the manufacturing steps shown and described herein with respect FIG. 11, which may create the lateral semiconductor device 650.

In some embodiments, the lateral semiconductor device 650 may be formed from the doped silicon stack 600 and may include a substrate region 652, where the substrate region 652 may be the same as the substrate region 602 of the doped silicon stack 600. Additionally, or alternatively, the lateral semiconductor device 650 may include a doped region 654, where the doped region 654 may be the same as the doped region 604 of the doped silicon stack 600 and where the doped region 654 includes a density of nanostructures 664 and at least two tunnel junctions 658 and 659. In some embodiments, the lateral semiconductor device 650 may include an insulating region 656, where the insulating region 656 may be the same as the insulating region 606. Further, the lateral semiconductor device 650 may include a source contact 660 and a drain contact 662 proximate the doped region 654, where, in an operative state, the source contact 660 and the drain contact 662 may be configured to be coupled to the nanostructures 664 of the doped region 654. In other words, the lateral semiconductor device 650 may be manufactured from a doped silicon stack 600 with a source contact 660 and a drain contact 662 deposited proximate the doped region 654.

In some embodiments, the tunnel junctions 658 and 659 may be configured to isolate a nanostructure 664 of the doped region 654 from other parts of the lateral semiconductor device 650. Further, the tunnel junctions 658 and 659 may be configured to allow particles (e.g., electrons) to tunnel through the tunnel junctions 658 and 659. Additionally, or alternatively, the tunnel junctions 658 and 659 may be configured to not allow particles to tunnel through the tunnel junctions 658 and 659. As will be appreciated by one of ordinary skill in the art in view of the present disclosure, the ability of a particle to tunnel through a tunnel barrier may be influenced by the energy of the particle in relation to the energy level of where the particle is tunneling.

In some embodiments, the source contact 660 and the drain contact 662 may be configured to have a bias voltage between one another. In some embodiments, under a structure dependent bias voltage of the source contact 660 and the drain contact 662, the lateral semiconductor device 650 may be configured to enable a particle to tunnel through the tunnel junction 658 and/or the tunnel junction 659. Additionally, or alternatively, under a bias voltage of the source contact 660 and the drain contact 662 less than the structure dependent bias voltage of the source contact 660 and the drain contact 662, the lateral semiconductor device 650 may be configured to enable a particle to not tunnel through the tunnel junction 658 and/or the tunnel junction 659. As will be appreciated by one of ordinary skill in the art in view of the present disclosure, controlling the bias voltages applied to the lateral semiconductor device 650 may allow control of the transmission of a particle through the lateral semiconductor device 650 which may control a current through the lateral semiconductor device 650. Further, controlling the transmission of a particle through the lateral semiconductor device 650 in such a manner may cause the current through the lateral semiconductor device 650 to be quantized.

As will be appreciated by one of ordinary skill in the art in view of the present disclosure, the method of manufacturing the lateral semiconductor device 650 may include additional embodiments, such as any single embodiment or any combination of embodiments described herein. Although FIG. 6 shows example steps of the method, in some embodiments, the method may include additional steps, fewer steps, different steps, or differently arranged steps than those depicted in FIG. 6. Furthermore, the lateral semiconductor device 650 may include other elements that are configured to control the barrier between a channel (e.g., a plurality of tunnel junctions and density of nanostructures between a source contact and drain contact) and the source contact 660 and the drain contact 662.

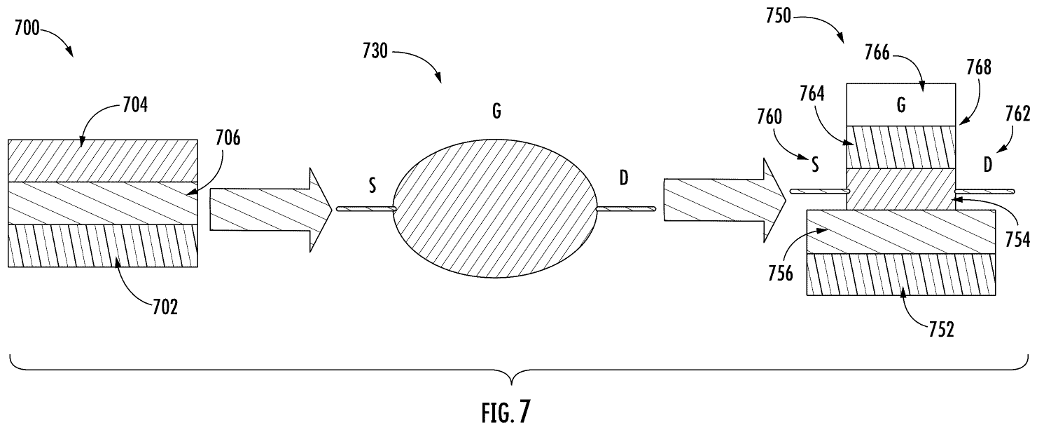

FIG. 7 schematically depicts a method of manufacturing a top gate semiconductor device 750, in accordance with an embodiment of the present disclosure. In some embodiments, creation of a top gate semiconductor device 750 may include a doped silicon stack 700 comprising a substrate region 702 (e.g., a layer of silicon), a doped region 704 (e.g., a layer of silicon with embedded nanostructures), and an insulating region 706 (e.g., a layer of silicon dioxide, dielectric material, and/or the like). Further, and in some embodiments, the insulating region 706 may be proximate the substrate region 702 such that the insulating region 706 may lie directly on the substrate region 702. Additionally, or alternatively, the doped region 704 may be proximate the insulating region 706 such that the doped region 704 may lie directly on the insulating region 706. In some embodiments, the insulating region 706 isolates the doped region 704 from the substrate region 702.

In some embodiments, the doped region 704 may include silicon containing a density of nanostructures (e.g., similar to the nanostructures 664 as shown and described herein with respect to FIG. 6) and a plurality of tunnel junctions (e.g., similar to the doped region 604 as shown and described herein with respect to FIG. 6). In some embodiments, the manufacturing of the doped silicon stack 700 may include any combination of the manufacturing steps shown and described herein with respect to FIG. 11. Additionally, or alternatively, the doped silicon stack 700 may undergo manufacturing steps 730, where the manufacturing steps 730 include any combination of the manufacturing steps shown and described herein with respect FIG. 11, which may create a top gate semiconductor device 750. For example, a source contact and a drain contact may be deposited on opposite sides across a doped region of a doped silicon stack. Further, an oxide region may be deposited proximate and/or on top of a doped silicon stack and a gate region may be deposited proximate and/or on top of the oxide region.

In some embodiments, the top gate semiconductor device 750 may be formed from the doped silicon stack 700 and may include a substrate region 752, where the substrate region 752 may be the same as the substrate region 702 of the doped silicon stack 700. Additionally, or alternatively, the top gate semiconductor device 750 may include a doped region 754, where the doped region 754 may be the same as the doped region 704 of the doped silicon stack 700 and where the doped region 754 includes a density of nanostructures and a plurality of tunnel junctions. In some embodiments, the top gate semiconductor device 750 may include an insulating region 756, where the insulating region 756 may be the same as the insulating region 706. Further, the top gate semiconductor device 750 may include a source contact 760 and a drain contact 762 proximate the doped region 754, where, in an operative state, the source contact 760 and the drain contact 762 may be configured to be coupled to the nanostructures of the doped region 754. Additionally, or alternatively, the top gate semiconductor device 750 may include an oxide region 764 proximate the doped region 754 and a gate region 766 proximate the oxide region 764, where the oxide region 764 may be configured to insulate the doped region 754 from the gate region 766. In some embodiments, the oxide region 764 may be configured as a dielectric region for a gate capacitor 268. In other words, the top gate semiconductor device 750 may be manufactured from a doped silicon stack 700 with a source contact 760 and a drain contact 762 deposited proximate the doped region 754 and an oxide region 764 deposited proximate the doped region 754 with a gate region 766 deposited proximate the oxide region 764.

In some embodiments, the plurality of tunnel junctions may be configured to isolate at least one nanostructure of the density of nanostructures of the doped region 754 from other parts of the top gate semiconductor device 750. Further, the plurality of tunnel junctions may be configured to allow particles (e.g., electrons) to tunnel through the plurality of tunnel junctions. Additionally, or alternatively, the plurality of tunnel junctions may be configured to not allow particles to tunnel through the plurality of tunnel junctions. As will be appreciated by one of ordinary skill in the art in view of the present disclosure, the ability of a particle to tunnel through a tunnel barrier may be influenced by the energy of the particle in relation to the energy level of where the particle is tunneling.

In some embodiments, the source contact 760 and the drain contact 762 may be configured to have a bias voltage between one another. In some embodiments, under a structure dependent bias voltage of the source contact 760 and drain contact 762, the top gate semiconductor device 750 may be configured to enable a particle to tunnel through at least one tunnel junction of the plurality of tunnel junctions. Additionally, or alternatively, under a bias voltage of the source contact 760 and the drain contact 762 less than the structure dependent bias voltage of the source contact 760 and the drain contact 762, the top gate semiconductor device 750 may be configured to enable a particle to not tunnel through the one or more tunnel junctions of the plurality of tunnel junctions. As will be appreciated by one of ordinary skill in the art in view of the present disclosure, controlling the bias voltages applied to the top gate semiconductor device 750 may allow control of the transmission of a particle through the top gate semiconductor device 750 which may control a current through the top gate semiconductor device 750.

In some embodiments, a voltage may be applied to the gate region 766. Additionally, or alternatively, the gate region 766 may be configured to transfer energy to the doped region 754 (e.g., through capacitive coupling). In some embodiments, the gate region 766 may be configured to shift the energy levels of at least one nanostructure of the density of nanostructures via adjusting the applied voltage to the gate region 766. Further, by shifting the energy levels, tunneling of a particle through at least one tunnel junction of the plurality of tunnel junctions may occur. Additionally, or alternatively, by shifting the energy levels, tunneling of a particle through at least one tunnel junction of the plurality of tunnel junctions may not occur.

In some embodiments, controlling the transmission of a particle through the top gate semiconductor device 750 in such a manner may cause the current through the top gate semiconductor device 750 to be quantized. As will be appreciated by one of ordinary skill in the art in view of the present disclosure, transmission of a particle and/or an electron through the top gate semiconductor device 750 may be controlled by adjusting the bias voltage across the source contact 760 and the drain contact 762, by adjusting the voltage applied to the gate region 766, and/or a combination of both.

As will be appreciated by one of ordinary skill in the art in view of the present disclosure, the method of manufacturing the top gate semiconductor device 750 may include additional embodiments, such as any single embodiment or any combination of embodiments described herein. Although FIG. 7 shows example steps of the method, in some embodiments, the method may include additional steps, fewer steps, different steps, or differently arranged steps than those depicted in FIG. 7. Furthermore, the top gate semiconductor device 750 may include other elements that are configured to control the barrier between a channel (e.g., a plurality of tunnel junctions and density of nanostructures between a source contact and drain contact) and the source contact 760 and the drain contact 762.

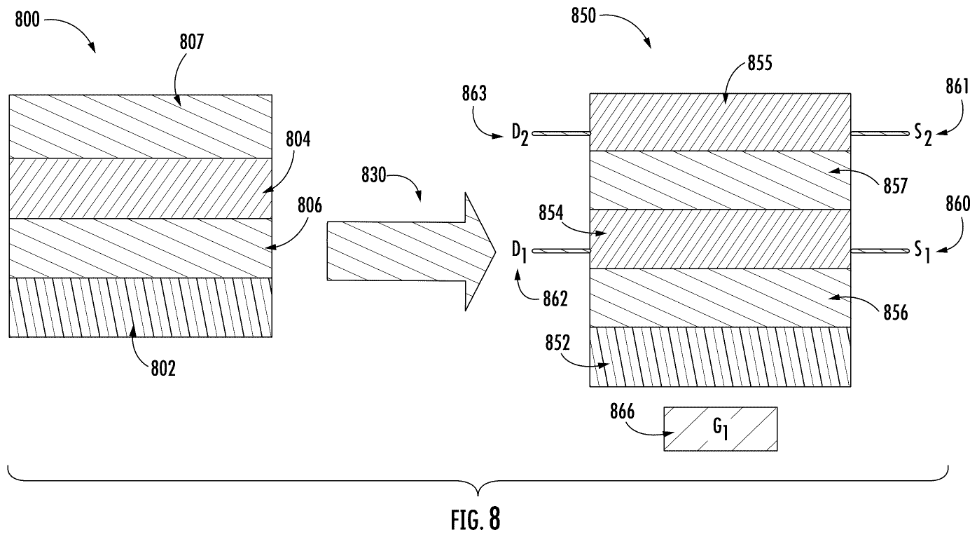

FIG. 8 schematically depicts a method of manufacturing a gate-all-around semiconductor device 850, in accordance with an embodiment of the present disclosure. In some embodiments, creation of the gate-all-around semiconductor device 850 may include a doped silicon stack 800 comprising a substrate region 802 (e.g., a layer of silicon), a doped region 804 (e.g., a layer of silicon with embedded nanostructures), a first insulating region 806 (e.g., a layer of silicon dioxide, dielectric material, and/or the like), and a second insulating region 807 (e.g., a layer of silicon dioxide, dielectric material, and/or the like). Further, and in some embodiments, the first insulating region 806 may be proximate the substrate region 802 such that the first insulating region 806 may lie directly on the substrate region 802. Additionally, or alternatively, the doped region 804 may be proximate the first insulating region 806 such that the doped region 804 may lie directly on the first insulating region 806. In some embodiments, the first insulating region 806 may isolate the doped region 804 from the substrate region 802. Additionally, or alternatively, the second insulating region 807 may be proximate the doped region 804 such that the second insulating region 807 may lie directly on the doped region 804.

In some embodiments, the doped region 804 may include silicon containing a density of nanostructures (e.g., similar to the nanostructures 664 as shown and described herein with respect to FIG. 6) and a plurality of tunnel junctions (e.g., similar to the doped region 654 as shown and described herein with respect to FIG. 6). In some embodiments, the manufacturing of the doped silicon stack 800 may include any combination of the manufacturing steps shown and described herein with respect to FIG. 11. Additionally, or alternatively, the doped silicon stack 800 may undergo manufacturing steps 830, where the manufacturing steps 830 include any combination of the manufacturing steps shown and described herein with respect FIG. 11, which may create the gate-all-around semiconductor device 850.

In some embodiments, the gate-all-around semiconductor device 850 may be formed from the doped silicon stack 800 and may include a substrate region 852, where the substrate region 852 may be the same as the substrate region 802 of the doped silicon stack 800. Additionally, or alternatively, the gate-all-around semiconductor device 850 may include a first doped region 854, where the first doped region 854 may be the same as the doped region 804 of the doped silicon stack 800 and where the first doped region 854 includes a density of nanostructures and a first plurality of tunnel junctions. In some embodiments, the gate-all-around semiconductor device 850 may include a first insulating region 856, where the first insulating region 856 may be the same as the first insulating region 806. Additionally, or alternatively, the gate-all-around semiconductor device 850 may include a second insulating region 857, where the second insulating region 857 may be the same as the second insulating region 807. In some embodiments, the gate-all-around semiconductor device 850 may include a second doped region 855, where the second doped region 855 may include a density of nanostructures and a second plurality of tunnel junctions. Further, the gate-all-around semiconductor device 850 may include a first source contact 860 and a first drain contact 862 proximate the first doped region 854, where, in an operative state, the first source contact 860 and the first drain contact 862 may be configured to be coupled to the nanostructures of the first doped region 854. Additionally, or alternatively, the gate-all-around semiconductor device 850 may include a second source contact 861 and a second drain contact 863 proximate the second doped region 855, where, in an operative state, the second source contact 861 and the second drain contact 863 may be configured to be coupled to the nanostructures of the second doped region 855.

In some embodiments, the gate-all-around semiconductor device 850 may include a gate-all-around region 866 which may be proximate the entirety of the gate-all-around semiconductor device 850. Additionally, or alternatively, the gate-all-around region 866 may include an oxide region, where the oxide region may be configured to insulate the gate-all-around semiconductor device 850 from the gate-all-around region 866. In other words, the gate-all-around semiconductor device 850 may be manufactured from a doped silicon stack 800 with a first source contact 860 and first drain contact 862 deposited proximate the first doped region 854, a second source contact 861 and second drain contact 863 deposited proximate the second doped region 855, and a gate-all-around region 866 which may be deposited proximate the entirety of the gate-all-around semiconductor device 850.

In some embodiments, the plurality of tunnel junctions of the first doped region 854 and/or the second doped region 855 may be configured to isolate at least one nanostructure of the density of nanostructures of the first doped region 854 and/or second doped region 855 from other parts of the gate-all-around semiconductor device 850. Further, the plurality of tunnel junctions of the first doped region 854 and/or second doped region 855 may be configured to allow particles (e.g., electrons) to tunnel through the plurality of tunnel junctions of the first doped region 854 and/or second doped region 855. Additionally, or alternatively, the plurality of tunnel junctions of the first doped region 854 and/or second doped region 855 may be configured to not allow particles to tunnel through the plurality of tunnel junctions of the first doped region 854 and/or second doped region 855. As will be appreciated by one of ordinary skill in the art in view of the present disclosure, the ability of a particle to tunnel through a tunnel barrier may be influenced by the energy of the particle in relation to the energy level of where the particle is tunneling.

In some embodiments, the first source contact 860 and the first drain contact 862 may be configured to have a bias voltage between one another. Additionally, or alternatively, under a structure dependent bias voltage of the first source contact 860 and the first drain contact 862, the gate-all-around semiconductor device 850 may be configured to enable a particle to tunnel through at least one tunnel junction of the plurality of tunnel junctions of the first doped region 854. Further, under a bias voltage of the first source contact 860 and the first drain contact 862 less than the structure dependent bias voltage of the first source contact 860 and the first drain contact 862, the gate-all-around semiconductor device 850 may be configured to enable a particle to not tunnel through the one or more tunnel junctions of the plurality of tunnel junctions of the first doped region 854.

In some embodiments, the second source contact 861 and the second drain contact 863 may be configured to have a bias voltage between one another. Additionally, or alternatively, under a structure dependent bias voltage of the second source contact 861 and the second drain contact 863, the gate-all-around semiconductor device 850 may be configured to enable a particle to tunnel through at least one tunnel junction of the plurality of tunnel junctions of the second doped region 855. Further, under a bias voltage of the second source contact 861 and the second drain contact 863 less than the structure dependent bias voltage of the second source contact 861 and the second drain contact 863, the gate-all-around semiconductor device 850 may be configured to enable a particle to not tunnel through the one or more tunnel junctions of the plurality of tunnel junctions of the second doped region 855. As will be appreciated by one of ordinary skill in the art in view of the present disclosure, controlling the bias voltages applied to the gate-all-around semiconductor device 850 may allow control of the transmission of a particle through the gate-all-around semiconductor device 850 which may control a current through the gate-all-around semiconductor device 850.

In some embodiments, a voltage may be applied to the gate-all-around region 866. Additionally, or alternatively, the gate-all-around region 866 may be configured to transfer energy to the first doped region 854 and/or the second doped region 855 (e.g., through capacitive coupling). In some embodiments, the gate-all-around region 866 may be configured to shift the energy levels of at least one nanostructure of the density of nanostructures via adjusting the applied voltage to the gate-all-around region 866. Further, by shifting the energy levels, tunneling of a particle through at least one tunnel junction of the first and/or second plurality of tunnel junctions may occur. Additionally, or alternatively, by shifting the energy levels, tunneling of a particle through at least one tunnel junction of the first and/or second plurality of tunnel junctions may not occur.

In some embodiments, controlling the transmission of a particle through the gate-all-around semiconductor device 850 in such a manner may cause the current through the gate-all-around semiconductor device 850 to be quantized. As will be appreciated by one of ordinary skill in the art in view of the present disclosure, transmission of a particle and/or an electron through the gate-all-around semiconductor device 850 may be controlled by adjusting the bias voltage across the first source contact 860 and the first drain contact 862 and/or the second source contact 861 and the second drain contact 863, by adjusting the voltage applied to the gate-all-around region 866, and/or a combination of both.

As will be appreciated by one of ordinary skill in the art in view of the present disclosure, the method of manufacturing the gate-all-around semiconductor device 850 may include additional embodiments, such as any single embodiment or any combination of embodiments described herein. Although FIG. 8 shows example steps of the method, in some embodiments, the method may include additional steps, fewer steps, different steps, or differently arranged steps than those depicted in FIG. 8. Furthermore, the gate-all-around semiconductor device 850 may include other elements that are configured to control the barrier between a channel (e.g., a plurality of tunnel junctions and density of nanostructures between a source contact and drain contact) and a source contact and a drain contact.

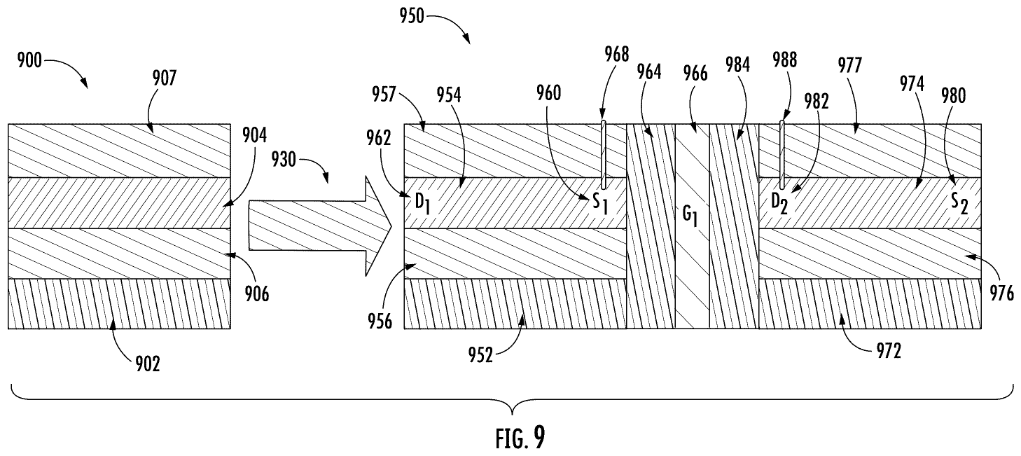

FIG. 9 schematically depicts a method of manufacturing two parallel lateral semiconductor devices 950 with a common vertical gate, in accordance with an embodiment of the present disclosure. In some embodiments, creation of the two parallel lateral semiconductor devices 950 may include a doped silicon stack 900 comprising a substrate region 902 (e.g., a layer of silicon), a doped region 904 (e.g., a layer of silicon with embedded nanostructures), a first insulating region 906 (e.g., a layer of silicon dioxide, dielectric material, and/or the like), and a second insulating region 907 (e.g., a layer of silicon dioxide, dielectric material, and/or the like). Further, and in some embodiments, the first insulating region 906 may be proximate the substrate region 902 such that the first insulating region 906 may lie directly on the substrate region 902. Additionally, or alternatively, the doped region 904 may be proximate the first insulating region 906 such that the doped region 904 may lie directly on the first insulating region 906. In some embodiments, the first insulating region 906 isolates the doped region 904 from the substrate region 902. Additionally, or alternatively, the second insulating region 907 may be proximate the doped region 904 such that the second insulating region 507 may lie directly on the doped region 904.

In some embodiments, the doped region 904 may include silicon containing a density of nanostructures (e.g., similar to the nanostructures 664 as shown and described herein with respect to FIG. 6) and a plurality of tunnel junctions (e.g., similar to the doped region 604 as shown and described herein with respect to FIG. 6). Additionally, or alternatively, the manufacturing of the doped silicon stack 900 may include any combination of the manufacturing steps shown and described herein with respect to FIG. 11. In some embodiments, the doped silicon stack 900 may undergo manufacturing steps 930, where the manufacturing steps 930 include any combination of the manufacturing steps shown and described herein with respect FIG. 11, which may create the two parallel lateral semiconductor devices 950.

In some embodiments, the two parallel lateral semiconductor devices 950 with a common vertical gate may be formed from the doped silicon stack 900 and/or a combination of doped silicon stacks similar to the doped silicon stack 900. Further, the two parallel lateral semiconductor devices 950 may include a first lateral semiconductor device substrate region 952, where the first lateral semiconductor device substrate region 952 may be the same as the substrate region 902 of the doped silicon stack 900. Additionally, or alternatively, the two parallel lateral semiconductor devices 950 may include a first lateral semiconductor device doped region 954, where the first lateral semiconductor device doped region 954 may be the same as the doped region 904 of the doped silicon stack 900 and where the first lateral semiconductor device doped region 954 may include a density of nanostructures and a first plurality of tunnel junctions. In some embodiments, the two parallel lateral semiconductor devices 950 may include a first lateral semiconductor device first insulating region 956, where the first lateral semiconductor device first insulating region 956 may be the same as the first insulating region 906. Additionally, or alternatively, the two parallel lateral semiconductor devices 950 may include a first lateral semiconductor device second insulating region 957, where the first lateral semiconductor device second insulating region 957 may be the same as the second insulating region 907. Further, the two parallel lateral semiconductor devices 950 may include a first lateral semiconductor device source contact 960 and a first lateral semiconductor device drain contact 962 proximate the first lateral semiconductor device doped region 954, where, in an operative state, the first lateral semiconductor device source contact 960 and the first lateral semiconductor device drain contact 962 may be configured to be coupled to the nanostructures of the first lateral semiconductor device doped region 954. In some embodiments, a first channel 968 may be used to electrically connect the first lateral semiconductor device source contact 960 to other circuitry.

In some embodiments, the two parallel lateral semiconductor device 950 may include a second lateral semiconductor device substrate region 972, where the second lateral semiconductor device substrate region 972 may be the same as the substrate region 902 of the doped silicon stack 900. Additionally, or alternatively, the two parallel lateral semiconductor device 950 may include a second lateral semiconductor device doped region 974, where the second lateral semiconductor device doped region 974 may be the same as the doped region 904 of the doped silicon stack 900 and where the second lateral semiconductor device doped region 974 may include a density of nanostructures and a second plurality of tunnel junctions. In some embodiments, the two parallel lateral semiconductor devices 950 may include a second lateral semiconductor device first insulating region 976, where the second lateral semiconductor device first insulating region 976 may be the same as the first insulating region 906. Additionally, or alternatively, the two parallel lateral semiconductor devices 950 may include a second lateral semiconductor device second insulating region 977, where the second lateral semiconductor device second insulating region 977 may be the same as the second insulating region 907. Further, the two parallel lateral semiconductor devices 950 may include a second lateral semiconductor device source contact 980 and a second lateral semiconductor device drain contact 982 proximate the second lateral semiconductor device doped region 974, where, in an operative state, the second lateral semiconductor device source contact 980 and the second lateral semiconductor device drain contact 982 may be configured to be coupled to the nanostructures of the second lateral semiconductor device doped region 974. In some embodiments, a second channel 988 may be used to electronically connect a second lateral semiconductor device drain contact 982 to other circuitry.

In some embodiments, the two parallel lateral semiconductor devices 950 may include a gate region 966. Additionally, or alternatively, the gate region 966 may include a first oxide region 964 and a second oxide region 984, where the first oxide region 964 and the second oxide region 984 may be configured to insulate the two parallel lateral semiconductor devices 950 from the gate region 966. In other words, the two parallel lateral semiconductor devices 950 may be manufactured from a doped silicon stack 900 and/or a combination of doped silicon stacks similar to the doped silicon stack 900 with a first lateral semiconductor device source contact 960 and first lateral semiconductor device drain contact 962 deposited proximate the first lateral semiconductor device doped region 954, a second lateral semiconductor device source contact 980 and second lateral semiconductor device drain contact 982 deposited proximate the second lateral semiconductor device doped region 975, a first oxide region 964 deposited proximate a side of the first lateral semiconductor device, a second oxide region 984 deposited proximate a side of the second lateral semiconductor device, and a gate region 966 which may be deposited between the first oxide region 964 and the second oxide region 984.

In some embodiments, the plurality of tunnel junctions of the first lateral semiconductor device doped region 954 and/or the second lateral semiconductor device doped region 974 may be configured to isolate at least one nanostructure of the density of nanostructures of the first lateral semiconductor device doped region 954 and/or second lateral semiconductor device doped region 974 from other parts of the two parallel lateral semiconductor devices 950. Further, the plurality of tunnel junctions of the first lateral semiconductor device doped region 954 and/or second lateral semiconductor device doped region 974 may be configured to allow particles (e.g., electrons) to tunnel through the plurality of tunnel junctions of the first lateral semiconductor device doped region 954 and/or second lateral semiconductor device doped region 974. Additionally, or alternatively, the plurality of tunnel junctions of the first lateral semiconductor device doped region 954 and/or second lateral semiconductor device doped region 974 may be configured to not allow particles to tunnel through the plurality of tunnel junctions of the first lateral semiconductor device doped region 954 and/or second lateral semiconductor device doped region 974. As will be appreciated by one of ordinary skill in the art in view of the present disclosure, the ability of a particle to tunnel through a tunnel barrier may be influenced by the energy of the particle in relation to the energy level of where the particle is tunneling.

In some embodiments, the first lateral semiconductor device source contact 960 and the first lateral semiconductor device drain contact 962 may be configured to have a bias voltage between one another. Additionally, or alternatively, under a structure dependent bias voltage of the first lateral semiconductor device source contact 960 and the first lateral semiconductor device drain contact 962, the two parallel lateral semiconductor devices 950 may be configured to enable a particle to tunnel through at least one tunnel junction of the plurality of tunnel junctions of the first lateral semiconductor device doped region 954. Further, under a bias voltage of the first lateral semiconductor device source contact 960 and the first lateral semiconductor device drain contact 962 less than the structure dependent bias voltage of the first lateral semiconductor device source contact 960 and the first lateral semiconductor device drain contact 962, the two parallel lateral semiconductor devices 950 may be configured to enable a particle to not tunnel through the one or more tunnel junctions of the plurality of tunnel junctions of the first lateral semiconductor device doped region 954.

In some embodiments, the second lateral semiconductor device source contact 961 and the second lateral semiconductor device drain contact 963 may be configured to have a bias voltage between one another. Additionally, or alternatively, under a structure dependent bias voltage of the second lateral semiconductor device source contact 961 and second lateral semiconductor device drain contact 963, the two parallel lateral semiconductor devices 950 may be configured to enable a particle to tunnel through at least one tunnel junction of the plurality of tunnel junctions of the second doped region 955. Further, under a bias voltage of the second lateral semiconductor device source contact 961 and the second lateral semiconductor device drain contact 963 less than the structure dependent bias voltage of the second lateral semiconductor device source contact 961 and the second lateral semiconductor device drain contact 963, the two parallel lateral semiconductor devices 950 may be configured to enable a particle to not tunnel through the one or more tunnel junctions of the plurality of tunnel junctions of the second doped region 955. As will be appreciated by one of ordinary skill in the art in view of the present disclosure, controlling the bias voltages applied to the two parallel lateral semiconductor devices 950 may allow control of the transmission of a particle through the two parallel lateral semiconductor devices 950 which may control a current through the two parallel lateral semiconductor devices 950.

In some embodiments, a voltage may be applied to the gate region 966. Additionally, or alternatively, the gate region 966 may be configured to transfer energy to the first lateral semiconductor device doped region 954 and/or the second lateral semiconductor device doped region 974 (e.g., through capacitive coupling). In some embodiments, the gate region 966 may be configured to shift the energy levels of at least one nanostructure of the density of nanostructures via adjusting the applied voltage to the gate region 966. Further, by shifting the energy levels, tunneling of a particle through at least one tunnel junction of the first and/or second plurality of tunnel junctions may occur. Additionally, or alternatively, by shifting the energy levels, tunneling of a particle through at least one tunnel junction of the first and/or second plurality of tunnel junctions may not occur.

In some embodiments, controlling the transmission of a particle through the two parallel lateral semiconductor devices 950 in such a manner may cause the current through the two parallel lateral semiconductor devices 950 to be quantized. As will be appreciated by one of ordinary skill in the art in view of the present disclosure, transmission of a particle and/or an electron through the two parallel lateral semiconductor devices 950 may be controlled by adjusting the bias voltage across the first lateral semiconductor device source contact 960 and the first lateral semiconductor device drain contact 962 and/or the second lateral semiconductor device source contact 980 and the second lateral semiconductor device drain contact 982, by adjusting the voltage applied to the gate region 966, and/or a combination of both.

As will be appreciated by one of ordinary skill in the art in view of the present disclosure, the method of manufacturing the two parallel lateral semiconductor devices with a common vertical gate may include additional embodiments, such as any single embodiment or any combination of embodiments described herein. Although FIG. 9 shows example steps of the method, in some embodiments, the method may include additional steps, fewer steps, different steps, or differently arranged steps than those depicted in FIG. 9. Furthermore, the two parallel lateral semiconductor devices 950 may include other elements that are configured to control the barrier between a channel (e.g., a plurality of tunnel junctions and density of nanostructures between a source contact and drain contact) and a source contact and a drain contact.

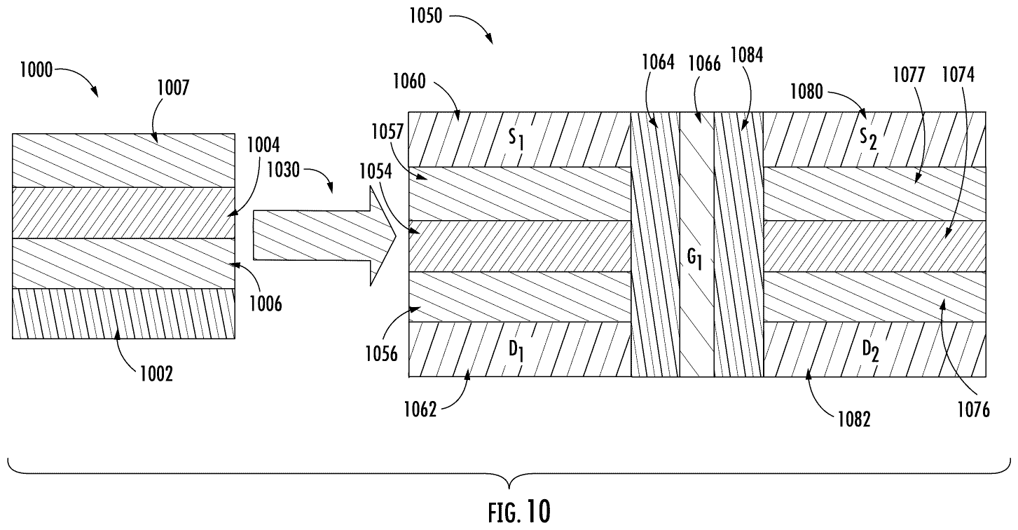

FIG. 10 schematically depicts a method of manufacturing of two parallel vertical semiconductor devices 1050 with a common vertical gate, in accordance with an embodiment of the present disclosure. In some embodiments, creation of the two parallel vertical semiconductor devices 1050 may include a doped silicon stack 1000 comprising a substrate region 1002 (e.g., a layer of silicon), a doped region 1004 (e.g., a layer of silicon with embedded nanostructures), a first insulating region 1006 (e.g., a layer of silicon dioxide, dielectric material, and/or the like), and a second insulating region 1007 (e.g., a layer of silicon dioxide, dielectric material, and/or the like). Further, and in some embodiments, the first insulating region 1006 may be proximate the substrate region 1002 such that the first insulating region 1006 may lie directly on the substrate region 1002. Additionally, or alternatively, the doped region 1004 may be proximate the first insulating region 1006 such that the doped region 1004 may lie directly on the first insulating region 1006. In some embodiments, the first insulating region 1006 isolates the doped region 1004 from the substrate region 1002. Additionally, or alternatively, the second insulating region 1007 may be proximate the doped region 1004 such that the second insulating region 1007 may lie directly on the doped region 1004.

In some embodiments, the doped region 1004 may include silicon containing a density of nanostructures (e.g., similar to the nanostructures 664 as shown and described herein with respect to FIG. 6) and a plurality of tunnel junctions (e.g., similar to the doped region 604 as shown and described herein with respect to FIG. 6). In some embodiments, the manufacturing of the doped silicon stack 1000 may include any combination of the manufacturing steps shown and described herein with respect to FIG. 11. Additionally, or alternatively, the doped silicon stack 1000 may undergo manufacturing steps 1030, where the manufacturing steps 1030 include any combination of the manufacturing steps shown and described herein with respect FIG. 11, which may create the two parallel vertical semiconductor devices 1050.

In some embodiments, the two parallel vertical semiconductor devices 1050 with a common vertical gate may be formed from the doped silicon stack 1000 and/or a combination of doped silicon stacks similar to the doped silicon stack 1000. Additionally, or alternatively, the two parallel vertical semiconductor devices 1050 may include a first vertical semiconductor device doped region 1054, where the first vertical semiconductor device doped region 1054 may be the same as the doped region 1004 of the doped silicon stack 1000 and where the first vertical semiconductor device doped region 1054 may include a density of nanostructures and a first plurality of tunnel junctions. In some embodiments, the two parallel vertical semiconductor devices 1050 may include a first vertical semiconductor device first insulating region 1056, where the first vertical semiconductor device first insulating region 1056 may be the same as the first insulating region 1006. Additionally, or alternatively, the two parallel vertical semiconductor devices 1050 may include a first vertical semiconductor device second insulating region 1057, where the first vertical semiconductor device second insulating region 1057 may be the same as the second insulating region 1007. Further, the two parallel vertical semiconductor devices 1050 may include a first vertical semiconductor device source contact 1060 proximate the first vertical semiconductor device second insulating region 1057 and a first vertical semiconductor device drain contact 1062 proximate the first vertical semiconductor device first insulating region 1056, where, in an operative state, the first vertical semiconductor device source contact 1060 and the first vertical semiconductor device drain contact 1062 may be configured to be coupled to the nanostructures of the first vertical semiconductor device doped region 1054.

In some embodiments, the two parallel vertical semiconductor devices 1050 may include a second vertical semiconductor device doped region 1074, where the second vertical semiconductor device doped region 1074 may be the same as the doped region 1004 of the doped silicon stack 1000 and where the second vertical semiconductor device doped region 1074 may include a density of nanostructures and a second plurality of tunnel junctions. In some embodiments, the two parallel vertical semiconductor devices 1050 may include a second vertical semiconductor device first insulating region 1076, where the second vertical semiconductor device first insulating region 1076 may be the same as the first insulating region 1006. Additionally, or alternatively, the two parallel semiconductor devices 1050 may include a second vertical semiconductor device second insulating region 1077, where the second vertical semiconductor device second insulating region 1077 may be the same as the second insulating region 1007. Further, the two parallel vertical semiconductor devices 1050 may include a second vertical semiconductor device source contact 1080 proximate the second vertical semiconductor device second insulating region 1077 and a second vertical semiconductor device drain contact 1082 proximate the second vertical semiconductor device first insulating region 1076, where, in an operative state, the second vertical semiconductor device source contact 1080 and the second vertical semiconductor device drain contact 1082 may be configured to be coupled to the nanostructures of the second vertical semiconductor device doped region 1074.

In some embodiments, the two parallel vertical semiconductor devices 1050 may include a gate region 1066. Additionally, or alternatively, the gate region 1066 may include a first oxide region 1064 and a second oxide region 1084, where the first oxide region 1064 and the second oxide region 1084 may be configured to insulate the two parallel vertical semiconductor devices 1050 from the gate region 1066. In other words, the two parallel vertical semiconductor devices 1050 may be manufactured from a doped silicon stack 1000 and/or a combination of doped silicon stacks similar to the doped silicon stack 1000 with a first vertical semiconductor device source contact 1060 deposited proximate the first vertical semiconductor device second insulating region 1057, a first vertical semiconductor device drain contact 1062 deposited proximate the first vertical semiconductor device first insulating region 1056, a second vertical semiconductor device source contact 1080 deposited proximate the second vertical semiconductor device second insulating region 1077, a second vertical semiconductor device drain contact 1082 deposited proximate the second vertical semiconductor device first insulating region 1076, a first oxide region 1064 deposited proximate a side of the first vertical semiconductor device, a second oxide region 1084 deposited proximate a side of the second vertical semiconductor device, and a gate region 1066 which may be deposited between the first oxide region 1064 and the second oxide region 1084.

In some embodiments, the plurality of tunnel junctions of the first vertical semiconductor device doped region 1054 and/or the second vertical semiconductor device doped region 1074 may be configured to isolate at least one nanostructure of the density of nanostructures of the first vertical semiconductor device doped region 1054 and/or second vertical semiconductor device doped region 1074 from other parts of the two parallel vertical semiconductor devices 1050. Further, the plurality of tunnel junctions of the first vertical semiconductor device doped region 1054 and/or second vertical semiconductor device doped region 1074 may be configured to allow particles (e.g., electrons) to tunnel through the plurality of tunnel junctions of the first vertical semiconductor device doped region 1054 and/or second vertical semiconductor device doped region 1074. Additionally, or alternatively, the plurality of tunnel junctions of the first vertical semiconductor device doped region 1054 and/or second vertical semiconductor device doped region 1074 may be configured to not allow particles to tunnel through the plurality of tunnel junctions of the first vertical semiconductor device doped region 1054 and/or second vertical semiconductor device doped region 1074. As will be appreciated by one of ordinary skill in the art in view of the present disclosure, the ability of a particle to tunnel through a tunnel barrier may be influenced by the energy of the particle in relation to the energy level of where the particle is tunneling.

In some embodiments, the first vertical semiconductor device source contact 1060 and the first vertical semiconductor device drain contact 1062 may be configured to have a bias voltage between one another. Additionally, or alternatively, under a structure dependent bias voltage of the first vertical semiconductor device source contact 1060 and the first vertical semiconductor device drain contact 1062, the two parallel semiconductor devices 1050 may be configured to enable a particle to tunnel through at least one tunnel junction of the plurality of tunnel junctions of the first vertical semiconductor device doped region 1054. Further, under a bias voltage of the first vertical semiconductor device source contact 1060 and the first vertical semiconductor device drain contact 1062 less than the structure dependent bias voltage of the first vertical semiconductor device source contact 1060 and the first vertical semiconductor device drain contact 1062, the two parallel vertical semiconductor devices 1050 may be configured to enable a particle to not tunnel through the one or more tunnel junctions of the plurality of tunnel junctions of the first vertical semiconductor device doped region 1054.

In some embodiments, the second vertical semiconductor device source contact 1061 and the second vertical semiconductor device drain contact 1063 may be configured to have a bias voltage between one another. Additionally, or alternatively, under a structure dependent bias voltage of the second vertical semiconductor device source contact 1061 and second vertical semiconductor device drain contact 1063, the two parallel vertical semiconductor devices 1050 may be configured to enable a particle to tunnel through at least one tunnel junction of the plurality of tunnel junctions of the second doped region 1055. Further, under a bias voltage of the second vertical semiconductor device source contact 1061 and the second vertical semiconductor device drain contact 1063 less than the structure dependent bias voltage of the second vertical semiconductor device source contact 1061 and the second vertical semiconductor device drain contact 1063, the two parallel vertical semiconductor devices 1050 may be configured to enable a particle to not tunnel through the one or more tunnel junctions of the plurality of tunnel junctions of the second doped region 1055. As will be appreciated by one of ordinary skill in the art in view of the present disclosure, controlling the bias voltages applied to the two parallel vertical semiconductor devices 1050 may allow control of the transmission of a particle through the two parallel vertical semiconductor devices 1050 which may control a current through the two parallel vertical semiconductor devices 1050.

In some embodiments, a voltage may be applied to gate region 1066. Additionally, or alternatively, the gate region 1066 may be configured to transfer energy to the first vertical semiconductor device doped region 1054 and/or the second vertical semiconductor device doped region 1074 (e.g., through capacitive coupling). In some embodiments, the gate region 1066 may be configured to shift the energy levels of at least one nanostructure of the density of nanostructures via adjusting the applied voltage to the gate region 1066. Further, by shifting the energy levels, tunneling of a particle through at least one tunnel junction of the first and/or second plurality of tunnel junctions may occur. Additionally, or alternatively, by shifting the energy levels, tunneling of a particle through at least one tunnel junction of the first and/or second plurality of tunnel junctions may not occur.

In some embodiments, controlling the transmission of a particle through the two parallel vertical semiconductor devices 1050 in such a manner may cause the current through the two parallel vertical semiconductor devices 1050 to be quantized. As will be appreciated by one of ordinary skill in the art in view of the present disclosure, transmission of a particle and/or an electron through the two parallel vertical semiconductor devices 1050 may be controlled by adjusting the bias voltage across the first vertical semiconductor device source contact 1060 and the first vertical semiconductor device drain contact 1062 and/or the second vertical semiconductor device source contact 1080 and the second vertical semiconductor device drain contact 1082, by adjusting the voltage applied to the gate region 1066, and/or a combination of both.

As will be appreciated by one of ordinary skill in the art in view of the present disclosure, the method of manufacturing the two parallel vertical semiconductor devices 1050 with a common vertical gate may include additional embodiments, such as any single embodiment or any combination of embodiments described herein. Although FIG. 10 shows example steps of the method, in some embodiments, the method may include additional steps, fewer steps, different steps, or differently arranged steps than those depicted in FIG. 10. Furthermore, the two parallel vertical semiconductor devices 1050 may include other elements that are configured to control the barrier between a channel (e.g., a plurality of tunnel junctions and density of nanostructures between a source contact and drain contact) and a source contact and a drain contact.

FIG. 11 illustrates a method of manufacturing a nanomaterial-based semiconductor device, in accordance with an embodiment of the disclosure. In some embodiments, the method 1100 may be used to manufacture nanomaterial-based semiconductor devices with embedded nanostructures (e.g., similar to the lateral semiconductor device 650 shown and described herein with respect to FIG. 6, the top gate semiconductor device 750 shown and described herein with respect to FIG. 7, the gate-all-around semiconductor device 850 shown and described herein with respect to FIG. 8, the two parallel lateral semiconductor devices 950 shown and described herein with respect to FIG. 9, the two parallel vertical semiconductor devices 1050 shown and described herein with respect to FIG. 10, the stacked gate-all-around semiconductor devices 450 shown and described herein with respect to FIG. 4, the optical device 500 as shown and described herein with respect to FIG. 5, the lateral stacked structure 300 as shown and described herein with respect to FIG. 3A, the vertical stacked structure 350 as shown and described herein with respect to FIG. 3B, the semiconductor device 100 of FIG. 1, and/or the embedded nanostructure of FIG. 2).

As shown in block 1102, the method 1100 may include providing a semiconductor wafer including a doped region, a substrate region, and an insulating region disposed between the doped region and the substrate region, where the insulating region may be configured to insulate the doped region from the substrate region. In some embodiments, the doped region, the substrate region, and/or the insulating region may be similar to one or more of the doped regions, the substrate regions, and/or the insulating regions, respectively, as shown and described herein with respect to FIGS. 1-10.

As shown in block 1104, the method 1100 may include forming a source region on the doped region. In some embodiments, the source region may be similar to one or more of the source regions as shown and described herein with respect to FIGS. 1-10.

As shown in block 1106, the method 1100 may include forming a drain region on the doped region, where the doped region includes a nanostructure as a dopant of the doped region, a first tunnel junction configured to electrically isolate the nanostructure from the source region, and a second tunnel junction configured to electrically isolate the nanostructure from the drain region. In some embodiments, the first tunnel junction may have a first thickness between the nanostructure and the source region (e.g., a first thickness of 3 nm or less), and/or the second tunnel junction may have a second thickness between the nanostructure and the drain region (e.g., a second thickness of 3 nm or less). Additionally, or alternatively, the drain region may be similar to one or more of the drain regions as shown and described herein with respect to FIGS. 1-10.

In some embodiments, method 1100 may include forming an oxide region on the doped region. Additionally, or alternatively, the method 1100 may include forming a gate region on the oxide region. In some embodiments, the oxide region and/or the doped region may be similar to one or more of the oxide regions and/or the doped regions, respectively, as shown and described herein with respect to FIGS. 1-10.

In some embodiments, the doped region may be a first doped region, where the nanostructure is a first nanostructure, the source region may be a first source region, the drain region may be a first drain region, and/or the insulating region may be a first insulating region. Additionally, or alternatively, the semiconductor wafer may include a second doped region including a second nanostructure as a dopant of the second doped region, a third tunnel junction configured to electrically isolate the second nanostructure from a second source region, and a fourth tunnel junction configured to electrically isolate the second nanostructure from a second drain region. Further, the semiconductor wafer may include a second insulating region disposed between the first doped region and the second doped region, where the second insulating region may be configured to insulate the first doped region from the second doped region.

In some embodiments, the method 1100 may include forming the second source region on the second doped region. Additionally, or alternatively, the method 1100 may include forming the second drain region on the second doped region.

In some embodiments, the method 1100 may include forming a gate region on the first doped region and the second doped region. Additionally, or alternatively, the method 1100 may include forming a first gate region on the first doped region and/or forming a second gate region on the second doped region. In some embodiments, the second gate region may include a first distributed Bragg reflector. Further, the second insulating region may include a second distributed Bragg reflector. In some embodiments, the second doped region may be configured to emit light.

As will be appreciated by one of ordinary skill in the art in view of the present disclosure, the present disclosure may include and/or be embodied as an apparatus (including, for example, a photodetector, a device, and/or the like), as a method (including, for example, a manufacturing method, a computer-implemented process, and/or the like), or as any combination of the foregoing.

Although many embodiments of the present disclosure have just been described above, the present disclosure may be embodied in many different forms and should not be construed as limited to the embodiments set forth herein; rather, these embodiments are provided so that this disclosure will satisfy applicable legal requirements. Also, it will be understood that, where possible, any of the advantages, features, functions, devices, and/or operational aspects of any of the embodiments of the present disclosure described and/or contemplated herein may be included in any of the other embodiments of the present disclosure described and/or contemplated herein, and/or vice versa.

While certain exemplary embodiments have been described and shown in the accompanying drawings, it is to be understood that such embodiments are merely illustrative of and not restrictive on the broad disclosure and that this disclosure is not to be limited to the specific constructions and arrangements shown and described, as various other changes, combinations, omissions, modifications and substitutions, in addition to those set forth in the above paragraphs, are possible. In light of this disclosure, those skilled in the art will appreciate that various adaptations, modifications, and combinations of the just described embodiments may be configured without departing from the scope and spirit of the disclosure. Therefore, it is to be understood that, within the scope of the appended claims, the disclosure may be practiced other than as specifically described herein.

1. A semiconductor device, comprising:
a doped region comprising:
a nanostructure as a dopant of the doped region;
a first tunnel junction configured to electrically isolate the nanostructure from a source region; and
a second tunnel junction configured to electrically isolate the nanostructure from a drain region;
a substrate region; and
an insulating region disposed between the doped region and the substrate region, wherein the insulating region is configured to insulate the doped region from the substrate region.

2. The semiconductor device of claim 1, wherein the nanostructure has a largest dimension of 5 nanometers or less.

3. The semiconductor device of claim 1, wherein the first tunnel junction has a first thickness between the nanostructure and the source region of 3 nanometers or less, and wherein the second tunnel junction has a second thickness between the nanostructure and the drain region of 3 nanometers or less.

4. The semiconductor device of claim 1, wherein the source region and the drain region are disposed on the doped region.

5. The semiconductor device of claim 1, comprising a gate region configured for controlling a current through the doped region.

6. The semiconductor device of claim 5, comprising a gate capacitor disposed between the gate region and the doped region.

7. The semiconductor device of claim 6, wherein the gate capacitor comprises an oxide region.

8. The semiconductor device of claim 1, wherein the doped region is a first doped region, wherein the nanostructure is a first nanostructure, wherein the source region is a first source region, wherein the drain region is a first drain region, wherein the insulating region is a first insulating region, and wherein the semiconductor device comprises:
a second doped region comprising:
a second nanostructure as a dopant of the second doped region;
a third tunnel junction configured to electrically isolate the second nanostructure from a second source region; and
a fourth tunnel junction configured to electrically isolate the second nanostructure from a second drain region; and
a second insulating region disposed between the first doped region and the second doped region, wherein the second insulating region is configured to insulate the first doped region from the second doped region.

9. The semiconductor device of claim 8, comprising:
a first gate region configured for controlling a first current through the first doped region;
a second gate region configured for controlling a second current through the second doped region, wherein the second gate region comprises a first distributed Bragg reflector; and
a gate capacitor disposed between the second gate region and the second doped region;
wherein the second insulating region comprises a second distributed Bragg reflector; and
wherein the second doped region is configured to emit light.

10. An optical device, comprising:
a semiconductor structure comprising:
a first doped region comprising a first nanostructure as a first dopant of the first doped region;
a substrate region; and
a first insulating region disposed between the first doped region and the substrate region, wherein the first insulating region is configured to insulate the first doped region from the substrate region; and
a diode comprising:
a second doped region comprising a second nanostructure as a second dopant of the second doped region, wherein the second doped region is configured to emit light;
a gate region configured for controlling a current through the second doped region, wherein the gate region comprises a first distributed Bragg reflector; and
a second insulating region disposed between the second doped region and the first doped region, wherein the second insulating region is configured to insulate the second doped region from the first doped region, and wherein the second insulating region comprises a second distributed Bragg reflector.

11. The optical device of claim 10, wherein the semiconductor structure comprises:
a first tunnel junction configured to electrically isolate the first nanostructure from a first source region; and
a second tunnel junction configured to electrically isolate the first nanostructure from a first drain region.

12. The optical device of claim 11, wherein the diode comprises:
a third tunnel junction configured to electrically isolate the second nanostructure from a second source region; and
a fourth tunnel junction configured to electrically isolate the second nanostructure from a second drain region.

13. The optical device of claim 10, comprising a gate capacitor disposed between the gate region and the second doped region.

14. The optical device of claim 10, wherein the semiconductor structure comprises a first gate region configured for controlling a current through the first doped region, and wherein the gate region is a second gate region.

15. A method of manufacturing a semiconductor device, the method comprising:
providing a semiconductor wafer comprising a doped region, a substrate region, and an insulating region disposed between the doped region and the substrate region, wherein the insulating region is configured to insulate the doped region from the substrate region;
forming a source region on the doped region; and
forming a drain region on the doped region;
wherein the doped region comprises (i) a nanostructure as a dopant of the doped region, (ii) a first tunnel junction configured to electrically isolate the nanostructure from the source region, and (iii) a second tunnel junction configured to electrically isolate the nanostructure from the drain region.

16. The method of claim 15, comprising:
forming an oxide region on the doped region; and
forming a gate region on the oxide region.

17. The method of claim 15, wherein the doped region is a first doped region, wherein the nanostructure is a first nanostructure, wherein the source region is a first source region, wherein the drain region is a first drain region, wherein the insulating region is a first insulating region, and wherein the semiconductor wafer comprises:
a second doped region comprising (i) a second nanostructure as a dopant of the second doped region, (ii) a third tunnel junction configured to electrically isolate the second nanostructure from a second source region, and (iii) a fourth tunnel junction configured to electrically isolate the second nanostructure from a second drain region; and
a second insulating region disposed between the first doped region and the second doped region, wherein the second insulating region is configured to insulate the first doped region from the second doped region.

18. The method of claim 17, comprising:
forming the second source region on the second doped region; and
forming the second drain region on the second doped region.

19. The method of claim 17, comprising forming a gate region on the first doped region and the second doped region.

20. The method of claim 17, comprising:
forming a first gate region on the first doped region; and
forming a second gate region on the second doped region, wherein the second gate region comprises a first distributed Bragg reflector;
wherein the second insulating region comprises a second distributed Bragg reflector; and
wherein the second doped region is configured to emit light.
